(19) United States
(12) Patent Application Publication
(10) Pub. No.: US 2024/0421071 A1
(43) Pub. Date: Dec. 19, 2024

(54) SEMICONDUCTOR MEMORY DEVICE

(71) Applicant: Kioxia Corporation, Tokyo (JP)

(72) Inventors: Ha HOANG, Kuwana Mie (JP); Kazuhiro MATSUO, Kuwana Mie (JP); Mutsumi OKAJIMA, Yokkaichi Mie (JP); Takamitsu OCHI, Nagoya Aichi (JP); Tsuyoshi SUGISAKI, Yokkaichi Mie (JP); Isamu UJIIE, Yokkaichi Mie (JP)

(73) Assignee: Kioxia Corporation, Tokyo (JP)

(21) Appl. No.: 18/743,245

(22) Filed: Jun. 14, 2024

(30) Foreign Application Priority Data
Jun. 19, 2023 (JP) 2023-100328

(51) Int. Cl. H01L 23/522; G11C 5/06; H01L 23/528; H10B 41/10; H10B 41/27; H10B 43/10; H10B 43/27

(52) U.S. Cl. CPC H01L 23/5226; G11C 5/063; H01L 23/528; H01L 23/5283; H10B 41/10; H10B 41/27; H10B 43/10; H10B 43/27

(57) ABSTRACT

A semiconductor memory device includes a plurality of memory layers arranged in a first direction, a first via-wiring extending in the first direction, a second via-wiring in a position different from a position of the first via-wiring in a second direction and extending in the first direction. One of the plurality of memory layers includes a first wiring disposed between the first and the second via-wiring and extending in a third direction, a first semiconductor layer electrically connected to the first via-wiring, a first gate electrode opposed to the first semiconductor layer and electrically connected to the first wiring, a first memory portion electrically connected to the first semiconductor layer, a second semiconductor layer electrically connected to the second via-wiring, a second gate electrode opposed to the second semiconductor layer and electrically connected to the first wiring, and a second memory portion electrically connected to the second semiconductor layer.

### CROSS-REFERENCE TO RELATED APPLICATIONS

This application is based upon and claims the benefit of Japanese Patent Application No. 2023-100328, filed on Jun. 19, 2023, the entire contents of which are incorporated herein by reference.

### BACKGROUND

### Field

Embodiments described herein relate generally to a semiconductor memory device.

### Description of the Related Art

In accordance with an increasing high integration of a semiconductor memory device, an examination for converting the semiconductor memory device into a three-dimensional form has been in progress.

### BRIEF DESCRIPTION OF THE DRAWINGS

FIG. 1 is a schematic circuit diagram illustrating a configuration of a part of a semiconductor memory device according to a first embodiment;

FIG. 2 is a schematic perspective view illustrating a configuration of a part of the semiconductor memory device;

FIG. 3 is a schematic perspective view illustrating a configuration of a part of the semiconductor memory device;

FIG. 4 is a schematic perspective view illustrating a configuration of a part of the semiconductor memory device;

FIG. 5 is a schematic X-Y cross-sectional view illustrating a configuration of a part of the semiconductor memory device;

FIG. 6 is a schematic plan view illustrating a configuration of a part of the semiconductor memory device;

FIG. 7 is a schematic X-Y cross-sectional view illustrating a configuration of a part of the semiconductor memory device;

FIG. 8 is a schematic cross-sectional view illustrating a configuration of a part of the semiconductor memory device;

FIG. 9 is a schematic cross-sectional view for describing a manufacturing method of the semiconductor memory device;

FIG. 10 is a schematic cross-sectional view for describing the manufacturing method;

FIG. 11 is a schematic cross-sectional view for describing the manufacturing method;

FIG. 12 is a schematic cross-sectional view for describing the manufacturing method;

FIG. 13 is a schematic cross-sectional view for describing the manufacturing method;

FIG. 14 is a schematic cross-sectional view for describing the manufacturing method;

FIG. 15 is a schematic cross-sectional view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view for describing the manufacturing method;

FIG. 27 is a schematic cross-sectional view for describing the manufacturing method;

FIG. 28 is a schematic cross-sectional view for describing the manufacturing method;

FIG. 29 is a schematic cross-sectional view for describing the manufacturing method;

FIG. 30 is a schematic cross-sectional view for describing the manufacturing method;

FIG. 31 is a schematic cross-sectional view for describing the manufacturing method;

FIG. 32 is a schematic cross-sectional view for describing the manufacturing method;

FIG. 33 is a schematic cross-sectional view for describing the manufacturing method;

FIG. 34 is a schematic cross-sectional view for describing the manufacturing method;

FIG. 35 is a schematic cross-sectional view for describing the manufacturing method;

FIG. 36 is a schematic cross-sectional view for describing the manufacturing method;

FIG. 37 is a schematic cross-sectional view for describing the manufacturing method;

FIG. 38 is a schematic cross-sectional view for describing the manufacturing method;

FIG. 39 is a schematic cross-sectional view for describing the manufacturing method;

FIG. 40 is a schematic cross-sectional view for describing the manufacturing method;

FIG. 41 is a schematic cross-sectional view for describing the manufacturing method;

FIG. 42 is a schematic cross-sectional view for describing the manufacturing method;

FIG. 43 is a schematic cross-sectional view for describing the manufacturing method;

FIG. 44 is a schematic cross-sectional view for describing the manufacturing method;

FIG. 45 is a schematic cross-sectional view for describing the manufacturing method;

FIG. 46 is a schematic cross-sectional view for describing the manufacturing method;

FIG. 47 is a schematic cross-sectional view for describing the manufacturing method;

FIG. 48 is a schematic cross-sectional view for describing the manufacturing method;

FIG. 49 is a schematic cross-sectional view for describing the manufacturing method;

FIG. 50 is a schematic cross-sectional view for describing the manufacturing method;

FIG. 51 is a schematic cross-sectional view for describing the manufacturing method;

FIG. 52 is a schematic cross-sectional view for describing the manufacturing method;

FIG. 53 is a schematic cross-sectional view for describing the manufacturing method;

FIG. 54 is a schematic cross-sectional view for describing the manufacturing method;

FIG. 55 is a schematic cross-sectional view for describing the manufacturing method;

FIG. 56 is a schematic cross-sectional view for describing the manufacturing method;

FIG. 57 is a schematic cross-sectional view for describing the manufacturing method;

FIG. 58 is a schematic X-Y cross-sectional view for describing effects of the semiconductor memory device according to the first embodiment;

FIG. 59 is a schematic X-Y cross-sectional view for describing the effects of the semiconductor memory device according to the first embodiment;

FIG. 60 is a schematic X-Y cross-sectional view illustrating a configuration of a part of a semiconductor memory device according to a second embodiment;

FIG. 61 is a schematic X-Y cross-sectional view illustrating a configuration of a part of a semiconductor memory device according to a third embodiment;

FIG. 62 is a schematic X-Y cross-sectional view illustrating a configuration of a part of a semiconductor memory device according to a fourth embodiment;

FIG. 63 is a schematic plan view illustrating a configuration of a part of a semiconductor memory device according to a fifth embodiment;

FIG. 64 is a schematic X-Y cross-sectional view illustrating a configuration of a part of a semiconductor memory device according to a sixth embodiment;

FIG. 65 is a schematic plan view illustrating a configuration of a part of the semiconductor memory device;

FIG. 66 is a schematic X-Y cross-sectional view illustrating a configuration of a part of a semiconductor memory device according to a seventh embodiment;

FIG. 67 is a schematic X-Y cross-sectional view illustrating a configuration of a part of a semiconductor memory device according to an eighth embodiment;

FIG. 68 is a schematic plan view illustrating a configuration of a part of the semiconductor memory device;

FIG. 69 is a schematic plan view illustrating a configuration of a part of a semiconductor memory device according to a ninth embodiment;

FIG. 70 is a schematic X-Y cross-sectional view illustrating a configuration of a part of a semiconductor memory device according to a tenth embodiment;

FIG. 71 is a schematic plan view illustrating a configuration of a part of the semiconductor memory device;

FIG. 72 is a schematic circuit diagram illustrating a configuration of a part of a semiconductor memory device according to an eleventh embodiment;

FIG. 73 is a schematic perspective view illustrating a configuration of a part of the semiconductor memory device;

FIG. 74 is a schematic plan view illustrating a configuration of a part of the semiconductor memory device;

FIG. 75 is a schematic plan view illustrating a configuration of a part of a semiconductor memory device according to a twelfth embodiment;

FIG. 76 is a schematic plan view illustrating a configuration of a part of a semiconductor memory device according to a thirteenth embodiment;

FIG. 77 is a schematic plan view illustrating a configuration of a part of a semiconductor memory device according to a fourteenth embodiment; and

FIG. 78 is a schematic plan view illustrating a configuration of a part of a semiconductor memory device according to a fifteenth embodiment.

### DETAILED DESCRIPTION

A semiconductor memory device according to one embodiment comprises a substrate, a plurality of memory layers arranged in a first direction intersecting with a surface of the substrate, a first via-wiring extending in the first direction, and a second via-wiring in a position different from a position of the first via-wiring in a second direction intersecting with the first direction and extending in the first direction. One of the plurality of memory layers includes a first wiring disposed between the first via-wiring and the second via-wiring and extending in a third direction intersecting with the first direction and the second direction. One of the plurality of memory layers includes a first semiconductor layer electrically connected to the first via-wiring, a first gate electrode opposed to the first semiconductor layer and electrically connected to the first wiring, and a first memory portion electrically connected to the first semiconductor layer and disposed on an opposite side of the first wiring with respect to the first semiconductor layer in the second direction. One of the plurality of memory layers includes a second semiconductor layer electrically connected to the second via-wiring, a second gate electrode opposed to the second semiconductor layer and electrically connected to the first wiring, and a second memory portion electrically connected to the second semiconductor layer and disposed on an opposite side of the first wiring with respect to the second semiconductor layer in the second direction.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to “semiconductor memory device,” it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is electrically connected between” the second configuration and a third configuration, it may mean that the first configuration, the second configuration, and the third configuration are connected in series and the second configuration is electrically connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like is turned ON.

In this specification, a predetermined direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion on a side opposite to the substrate of this configuration. A surface intersecting with the X-direction or the Y-direction is referred to as a side surface and the like.

In this specification, a “center position” of a certain configuration may mean, for example, a position of the center of a circumscribed circle of this configuration and may mean the centroid on an image of this configuration on a predetermined plane.

### First Embodiment

### [Circuit Configuration]

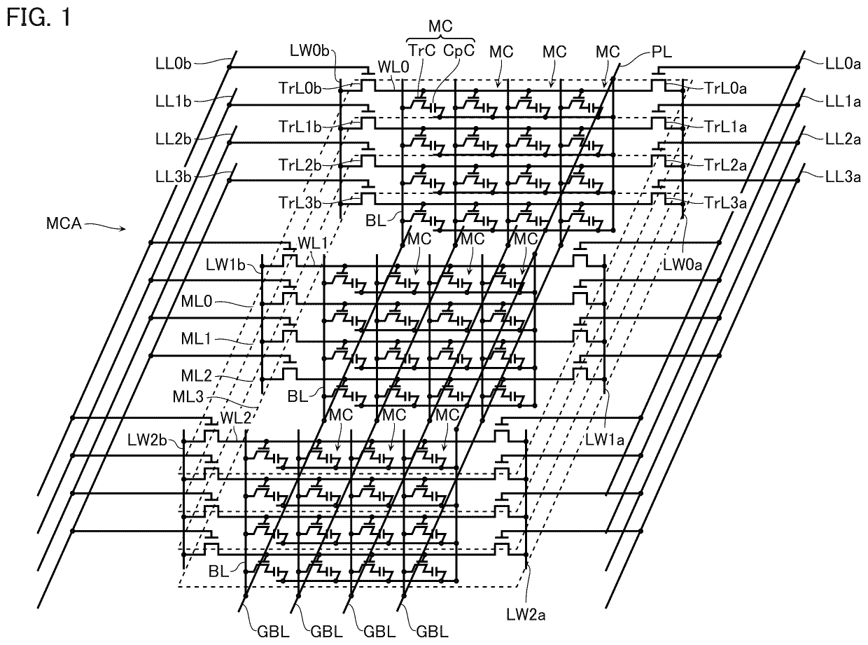

FIG. 1 is a schematic circuit diagram illustrating a configuration of a part of a semiconductor memory device according to the first embodiment. As illustrated in FIG. 1, the semiconductor memory device according to the embodiment includes a memory cell array MCA. The memory cell array MCA includes a plurality of memory layers ML0 to ML3, a plurality of bit lines BL connected to these plurality of memory layers ML0 to ML3, a plurality of global bit lines GBL electrically connected to the plurality of bit lines BL, and a plate line PL connected to the plurality of memory layers ML0 to ML3.

Each of the memory layers ML0 to ML3 includes a plurality of word lines WL0 to WL2 (hereinafter referred to as “word lines WL” in some cases) and a plurality of memory cells MC connected to these plurality of word lines WL0 to WL2. Each of the memory cells MC includes a transistor TrC and a capacitor CpC. A source electrode of the transistor TrC is connected to a bit line BL. A drain electrode of the transistor TrC is connected to the capacitor CpC. A gate electrode of the transistor TrC is connected to any of the word lines WL0 to WL2. One electrode of the capacitor CpC is connected to the drain electrode of the transistor TrC. The other electrode of the capacitor CpC is connected to the plate line PL.

Each of the bit lines BL is connected to the plurality of memory cells MC corresponding to the plurality of memory layers ML0 to ML3. In addition, each of the bit lines BL is connected to a global bit line GBL.

The respective memory layers ML0 to ML3 include a plurality of transistors TrL0a, TrL0b, TrL1a, TrL1b, TrL2a, TrL2b, TrL3a, TrL3b (hereinafter referred to as “transistors TrL” in some cases) disposed corresponding to the plurality of word lines WL0 to WL2. Drain electrodes of the transistors TrL are connected to any of the word lines WL0 to WL2. Source electrodes of the transistors TrL are connected to respective word line select lines LW0a, LW0b, LW1a, LW1b, LW2a, LW2b (hereinafter referred to as “word line select lines LW” in some cases). Gate electrodes of the transistors TrL are connected to respective layer select lines LL0a, LL0b, LL1a, LL1b, LL2a, LL2b, LL3a, LL3b (hereinafter referred to as “layer select lines LL” in some cases).

The word line select lines LW are connected to the plurality of transistors TrL corresponding to the plurality of memory layers ML0 to ML3. Furthermore, the layer select lines LL0a, LL1a, LL2a, LL3a are connected in common to all the respective transistors TrL0a, TrL1a, TrL2a, TrL3a corresponding to the memory layers ML0 to ML3. Similarly, the layer select lines LL0b, LL1b, LL2b, LL3b are connected in common to all the respective transistors TrL0b, TrL1b, TrL2b, TrL3b corresponding to the memory layers ML0 to ML3.

### [Structure]

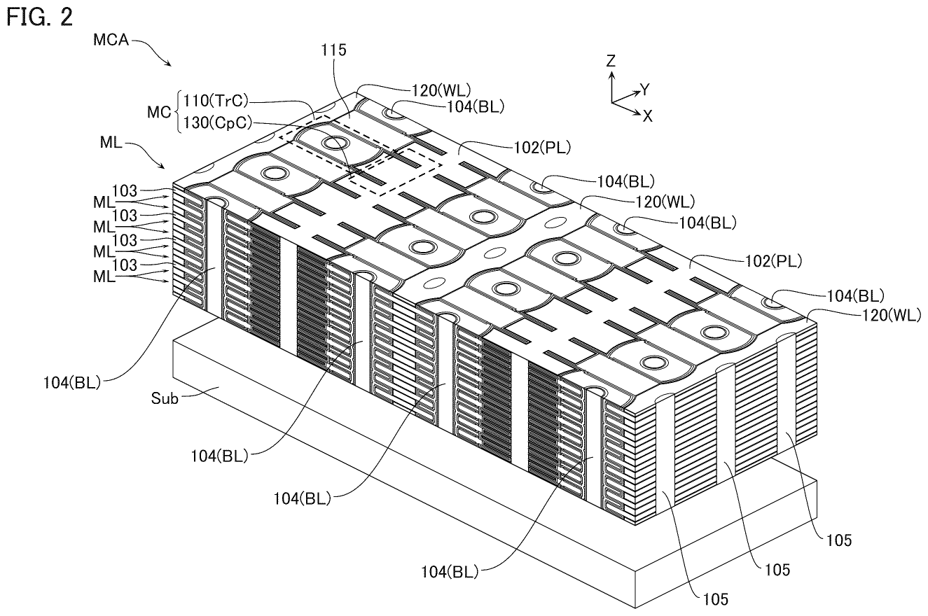

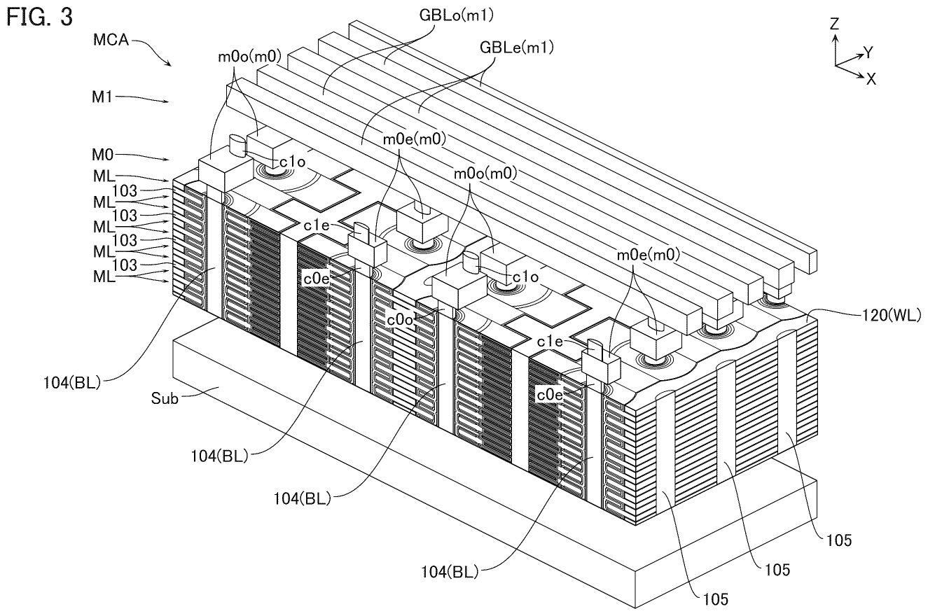

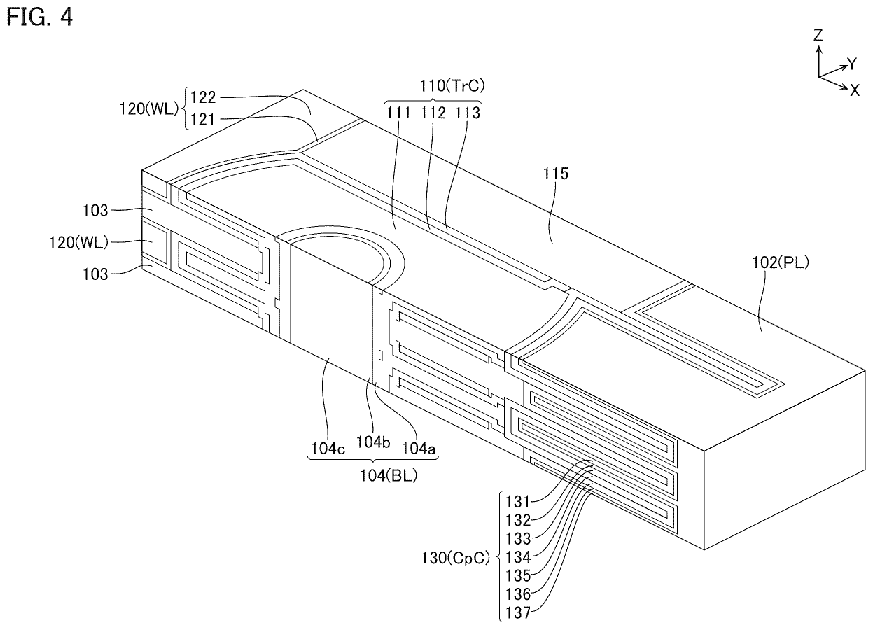

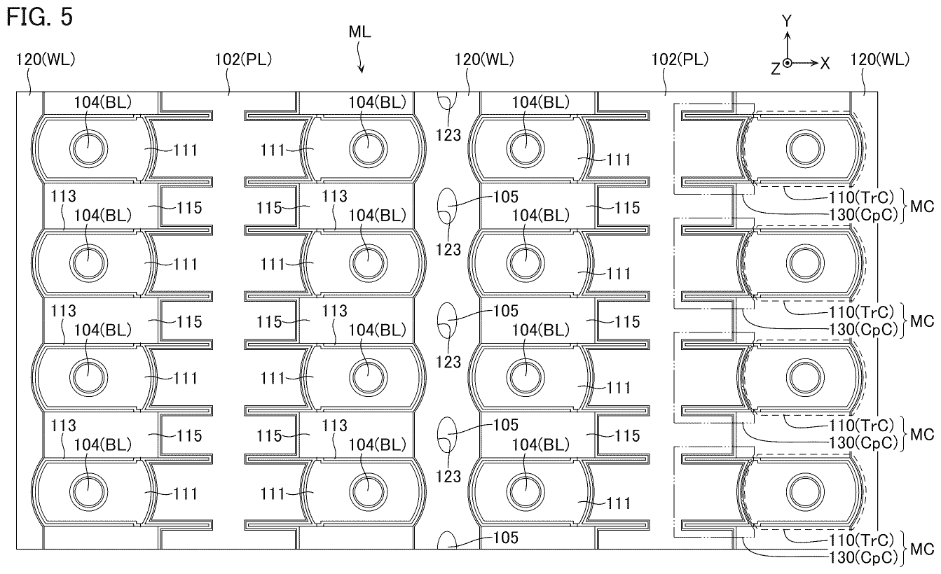

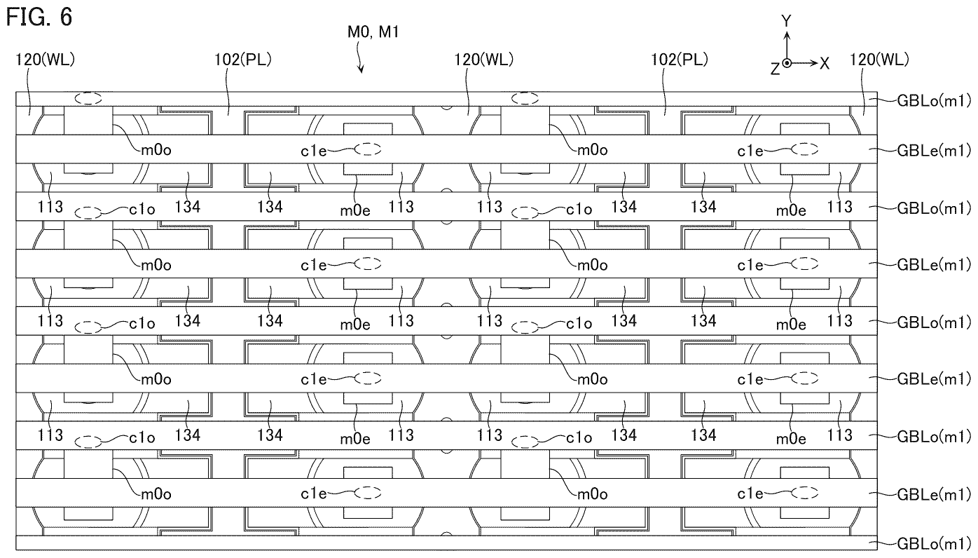

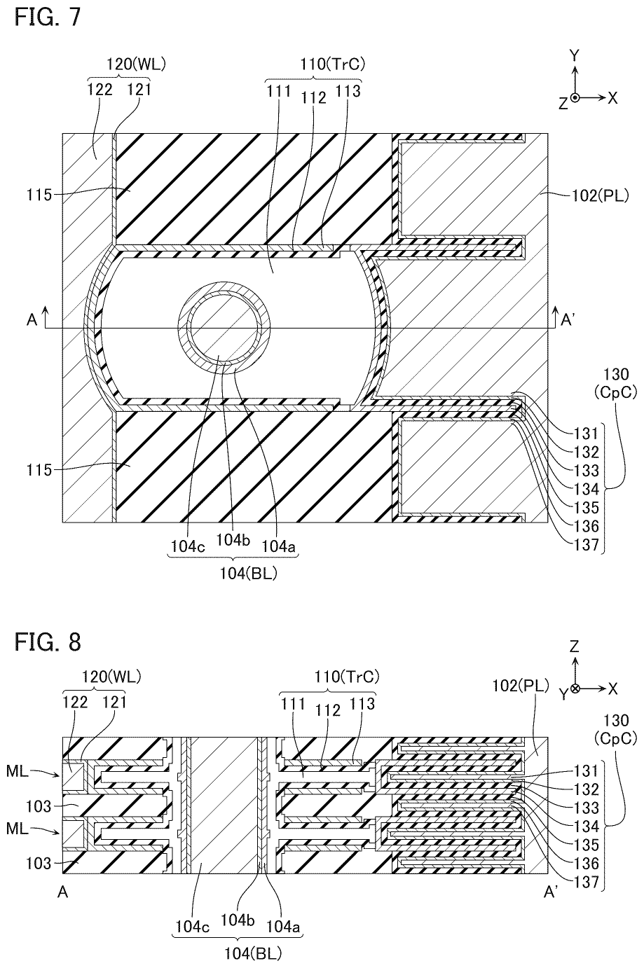

FIG. 2 and FIG. 3 are schematic perspective views illustrating configurations of parts of the semiconductor memory device according to the first embodiment. In FIG. 3, the configuration of a part that is omitted in FIG. 2 is illustrated. FIG. 4 is a schematic perspective view illustrating a configuration of a part of the semiconductor memory device and illustrates an enlarged part of FIG. 2. FIG. 5 is a schematic X-Y cross-sectional view illustrating a configuration of a part of the semiconductor memory device. FIG. 6 is a schematic plan view illustrating a configuration of a part of the semiconductor memory device. FIG. 7 is a schematic X-Y cross-sectional view illustrating a configuration of a part of the semiconductor memory device and illustrates an enlarged part of FIG. 5. FIG. 8 is a schematic cross-sectional view illustrating a configuration of a part of the semiconductor memory device and illustrates the configuration in which the structure illustrated in FIG. 7 is taken along the line A-A′ and viewed along an arrow direction.

FIG. 2 and FIG. 3 illustrate parts of a semiconductor substrate Sub and a memory cell array MCA disposed above the semiconductor substrate Sub.

The semiconductor substrate Sub is, for example, a semiconductor substrate of silicon (Si) or the like containing P-type impurities, such as boron (B). An insulating layer and an electrode layer (not illustrated in FIG. 2 and FIG. 3) are disposed on an upper surface of the semiconductor substrate Sub. The upper surface of the semiconductor substrate Sub, the insulating layer, and the electrode layer (not illustrated FIG. 2 and FIG. 3) constitute a control circuit for controlling the semiconductor memory device according to the first embodiment. For example, a sense amplifier circuit is disposed in a region immediately below the memory cell array MCA. The sense amplifier circuit is electrically connected to the bit lines BL. The sense amplifier circuit can read the data stored in a selected memory cell MC by detecting the voltage variation or the current of the bit line BL in a read operation.

The memory cell array MCA includes a plurality of memory layers ML arranged in the Z-direction. An insulating layer 103 of, for example, silicon oxide (SiO₂) is disposed between the respective plurality of memory layers ML.

In addition, in the memory cell array MCA, a plurality of structures penetrating the plurality of memory layers ML and extending in the Z-direction and wiring layers M0, M1 (FIG. 3) disposed above the plurality of memory layers ML are disposed.

The plurality of structures penetrating the plurality of memory layers ML and extending in the Z-direction, the plurality of memory layers ML, and the wiring layers M0, M1 will be sequentially described below.

### [Plurality of Structures Penetrating Plurality of Memory Layers ML and Extending in Z-Direction]

In the memory cell array MCA, a plurality of conductive members 102 arranged in the X-direction are disposed. Each of these plurality of conductive members 102 extends in the Y-direction and the Z-direction and separates the memory layers ML in the X-direction.

The conductive member 102 includes, for example, a stacked structure of titanium nitride (TiN) and tungsten (W), or the like. The conductive member 102 functions as, for example, the plate line PL (FIG. 1).

A plurality of via wirings 104 arranged in the Y-direction are disposed in a region between the conductive member 102 and a conductive layer 120 described later in the memory cell array MCA. Each of these plurality of via wirings 104 penetrates the plurality of memory layers ML and extends in the Z-direction.

As illustrated in FIG. 4, for example, the via wiring 104 includes a conductive oxide film 104a containing a conductive oxide, a barrier conductive film 104b of, for example, titanium nitride (TiN), and a conductive member 104c of, for example, tungsten (W). The via wiring 104 may contain ruthenium (Ru), iridium (Ir), or another metal instead of the conductive oxide film 104a. Furthermore, the via wiring 104 may contain only a conductive oxide or may contain only ruthenium (Ru), iridium (Ir), or another metal.

In this specification, the “conductive oxide” includes a conductive material containing, for example, indium tin oxide (ITO), indium zinc oxide (IZO), ruthenium oxide (RuO₂), iridium oxide (IrO₂), or another oxygen.

The conductive member 104c has an approximately columnar shape extending in the Z-direction. The barrier conductive film 104b has an approximately cylindrical shape extending in the Z-direction along an outer peripheral surface of the conductive member 104c. The conductive oxide film 104a has an approximately cylindrical shape extending in the Z-direction along an outer peripheral surface of the barrier conductive film 104b. The via wiring 104 functions as, for example, the bit line BL (FIG. 1).

For example, as illustrated in FIG. 5, in the first embodiment, a plurality of via wirings 104 are disposed so as to form two rows that differ in position in the X-direction between two conductive members 102 adjacent in the X-direction. In focusing on these plurality of via wirings 104, a position in the Y-direction of one of the plurality of via wirings 104 included in one row approximately coincides with any of the positions in the Y-direction of the plurality of via wirings 104 included in the other row. In focusing on these plurality of via wirings 104, each of the positions in the Y-direction of the plurality of via wirings 104 included in the row disposed on one side in the X-direction with respect to the conductive layer 120 described later approximately coincides with any of the positions in the Y-direction of the plurality of via wirings 104 included in the row disposed on the other side in the X-direction with respect to the conductive layer 120.

In addition, in the first embodiment, a plurality of via wirings 104 are disposed so as to form two rows that differ in position in the X-direction between two conductive layers 120 adjacent in the X-direction. In focusing on these plurality of via wirings 104, a position in the Y-direction of one of the plurality of via wirings 104 included in one row approximately coincides with any of the positions in the Y-direction of the plurality of via wirings 104 included in the other row. In focusing on these plurality of via wirings 104, each of the positions in the Y-direction of the plurality of via wirings 104 included in the row disposed on one side in the X-direction with respect to the conductive member 102 approximately coincides with any of the positions in the Y-direction of the plurality of via wirings 104 included in the row disposed on the other side in the X-direction with respect to the conductive member 102.

A plurality of insulating members 105 arranged in the Y-direction are disposed along the conductive layers 120 in a region corresponding to the conductive layers 120 described later in the memory cell array MCA. Each of these plurality of insulating members 105 penetrates the plurality of memory layers ML and extends in the Z-direction. These plurality of insulating members 105 contain, for example, silicon oxide (SiO₂). In the illustrated example, a position in the X-direction of one of these plurality of insulating members 105 coincides with a middle position in the X-direction of the conductive layer 120. In the illustrated example, each of middle positions in the X-direction of these plurality of insulating members 105 coincides with a middle position in the X-direction of the conductive layer 120. Furthermore, in the illustrated example, the positions in the Y-direction of these plurality of insulating members 105 correspond to any of those of a plurality of insulating members 115 described later.

### [Structure of Memory Layer ML]

As illustrated in FIG. 5, for example, the memory layer ML includes: the conductive layers 120, each of which is disposed between two conductive members 102 adjacent in the X-direction and extends in the Y-direction; a plurality of transistor structures 110 disposed between a conductive member 102 and a conductive layer 120 and arranged in the Y-direction corresponding to the plurality of via wirings 104; and a plurality of capacitor structures 130 disposed between a conductive member 102 and a plurality of transistor structures 110 and arranged in the Y-direction corresponding to the plurality of via wirings 104.

As illustrated in FIG. 4, for example, the transistor structure 110 includes a semiconductor layer 111 connected to an outer peripheral surface of the via wiring 104 and extending in the X-direction, an insulating layer 112 disposed on an upper surface, a lower surface, both side surfaces in the Y-direction, and a side surface on one side in the X-direction (a conductive layer 120 side) of the semiconductor layer 111, and a conductive layer 113 disposed on an upper surface, a lower surface, both side surfaces in the Y-direction, and a side surface on one side in the X-direction (the conductive layer 120 side) of the insulating layer 112.

In the X-Y cross-sectional surface exemplarily illustrated in FIG. 7, each of both side surfaces in the X-direction of the semiconductor layer 111 may be formed along a circle around a center position of the via wiring 104. In addition, each of the side surfaces on one side in the X-direction (the conductive layer 120 side) of the insulating layer 112 and the conductive layer 113 may be similarly formed along the circle around the center position of the via wiring 104. Furthermore, both side surfaces in the Y-direction of the semiconductor layer 111, the insulating layer 112, and the conductive layer 113 may be linearly formed along the side surfaces of the insulating members 115.

Note that both side surfaces in the X-direction of the semiconductor layer 111 need not be formed along a circle. Even in such a case, for example, both side surfaces in the X-direction of the semiconductor layer 111 may form curved lines when viewed in the Z-direction. For example, the semiconductor layer 111 may have a length in the X-direction that differs depending on the position in the Y-direction. For example, the length in the X-direction of the semiconductor layer 111 at a position close to the insulating member 115 may be shorter than the length in the X-direction of the semiconductor layer 111 at a position far from the insulating member 115.

The semiconductor layer 111 functions as, for example, a channel region of the transistor TrC (FIG. 1).

The semiconductor layer 111 may be, for example, a semiconductor containing at least one element of gallium (Ga) and aluminum (Al), and containing indium (In), zinc (Zn), and oxygen (O), or may be another oxide semiconductor. A plurality of semiconductor layers 111 arranged in the Z-direction are connected in common to the via wiring 104 extending in the Z-direction.

The insulating layer 112 functions as, for example, a gate insulating film of the transistor TrC (FIG. 1). The insulating layer 112 contains, for example, silicon oxide (SiO₂) or the like.

The conductive layer 113 functions as, for example, a gate electrode of the transistor TrC (FIG. 1). The conductive layer 113 contains, for example, titanium nitride (TiN), or a conductive oxide such as indium tin oxide (ITO). As illustrated in FIG. 5, a plurality of conductive layers 113 arranged in the Y-direction are connected in common to the conductive layer 120 extending in the Y-direction. As illustrated in FIG. 7 and FIG. 8, the conductive layer 113 is opposed to the upper surface, the lower surface, both side surfaces in the Y-direction, and the side surface on one side in the X-direction (the conductive layer 120 side) of the semiconductor layer 111 via the insulating layer 112.

As illustrated in FIG. 5, the insulating member 115 of, for example, silicon oxide (SiO₂) is disposed between two semiconductor layers 111 adjacent in the Y-direction. The insulating member 115 penetrates the plurality of memory layers ML and extends in the Z-direction.

The conductive layer 120 functions as, for example, the word line WL (FIG. 1). The conductive layer 120 extends in the Y-direction as described above. Each of both side surfaces in the X-direction of the conductive layer 120 is connected to a plurality of conductive layers 113 arranged in the Y-direction. As illustrated in FIG. 7 and FIG. 8, the conductive layer 120 includes, for example, a barrier conductive film 121 of titanium nitride (TiN) or the like and a conductive film 122 of tungsten (W).

As illustrated in FIG. 5, the conductive layer 120 includes a plurality of through holes 123 arranged in the Y-direction along the plurality of insulating members 105 described above. Inner peripheral surfaces of these plurality of through holes 123 surround the respective insulating members 105 and are connected to outer peripheral surfaces of the insulating members 105.

As illustrated in FIG. 7 and FIG. 8, for example, the capacitor structure 130 includes: a conductive layer 131; a conductive layer 132 disposed on an upper surface, a lower surface, both side surfaces in the Y-direction, and a side surface on one side in the X-direction (a transistor structure 110 side) of the conductive layer 131; an insulating layer 133 disposed on an upper surface, a lower surface, both side surfaces in the Y-direction, and a side surface on one side in the X-direction (the transistor structure 110 side) of the conductive layer 132; a conductive layer 134 disposed on an upper surface, a lower surface, both side surfaces in the Y-direction, and a side surface on one side in the X-direction (the transistor structure 110 side) of the insulating layer 133; an insulating layer 135 disposed on an upper surface, a lower surface, and both side surfaces in the Y-direction of the conductive layer 134; a conductive layer 136 disposed on an upper surface, a lower surface, and both side surfaces in the Y-direction of the insulating layer 135; and a conductive layer 137 disposed on an upper surface, a lower surface, and both side surfaces in the Y-direction of the conductive layer 136.

The conductive layers 131, 132, 136, 137 function as one electrode of the capacitor CpC (FIG. 1). The conductive layers 131, 137 contain, for example, tungsten (W) or the like. The conductive layers 132, 136 contain, for example, titanium nitride (TiN) or the like. The conductive layers 131, 132, 136, 137 are connected to the conductive member 102.

The insulating layers 133, 135 function as insulating layers of the capacitor CpC (FIG. 1). The insulating layers 133, 135 may be, for example, zirconia (ZrO₂), alumina (Al₂O₃), or another insulating metal oxide. In addition, the insulating layers 133, 135 may be, for example, a stacked film of a plurality of insulating metal oxides (for example, a stacked film of zirconia and alumina).

The conductive layer 134 functions as, for example, the other electrode of the capacitor CpC (FIG. 1). The conductive layer 134 contains, for example, a conductive oxide, such as indium tin oxide (ITO). The conductive layer 134 is insulated from the conductive layers 131, 132, 136, 137 via the insulating layers 133, 135. The conductive layer 134 is connected to the side surface in the X-direction of the semiconductor layer 111.

### [Structures of Wiring Layers M0, M1]

As illustrated in FIG. 3, in the memory cell array MCA, the wiring layer M0 disposed above the plurality of memory layers ML and the wiring layer M1 disposed above the wiring layer M0 are disposed.

The wiring layer M1 includes a plurality of wirings m1. These plurality of wirings m1 may include, for example, a stacked film of a barrier conductive film of, for example, titanium nitride (TiN) and a metal film of, for example, tungsten (W) or copper (Cu), or the like. At least a part of the plurality of wirings m1 function as the global bit lines GBL (FIG. 1). The global bit lines GBL are arranged in the Y-direction and extend in the X-direction.

The wiring layer M0 includes a plurality of wirings mn. These plurality of wirings m0 may include, for example, a stacked film of a barrier conductive film of, for example, titanium nitride (TiN) and a metal film of, for example, tungsten (W) or copper (Cu), or the like. At least a part of the plurality of wirings m0 electrically connect the via wirings 104 functioning as the bit lines BL to the wirings m1 functioning as the global bit lines GBL.

Here, as described with reference to FIG. 5, each of both side surfaces in the X-direction of the conductive layer 120 is connected to a plurality of conductive layers 113 arranged in the Y-direction. In the embodiment, in order to achieve the memory cells MC of 1T1C type in such a configuration, the transistor structures 110 connected to the side surface on one side in the X-direction of the conductive layer 120 and the transistor structures 110 connected to the side surface on the other side in the X-direction of the conductive layer 120 are electrically connected to different global bit lines GBL.

For example, in the example of FIG. 6, among the plurality of global bit lines GBL arranged in the Y-direction, even-numbered global bit lines GBLe counted from a positive side in the Y-direction are disposed at positions that overlap with a plurality of corresponding bit lines BL when viewed in the Z-direction. Among the plurality of wirings m0, each of a plurality of wirings m0e connected to such global bit lines GBLe is disposed at a position that overlaps with the global bit line GBLe and the bit line BL when viewed in the Z-direction. In addition, each of the plurality of wirings m0e is electrically connected to the bit line BL via a via-contact electrode c0e (FIG. 3) extending in the Z-direction and electrically connected to the global bit line GBLe via a via-contact electrode c1e extending in the Z-direction.

Meanwhile, among the plurality of global bit lines GBL arranged in the Y-direction, odd-numbered global bit lines GBLo counted from a positive side in the Y-direction are disposed at positions that do not overlap with a plurality of corresponding bit lines BL when viewed in the Z-direction. Among the plurality of wirings m0, each of a plurality of wirings m0o connected to such global bit lines GBLo extends in the Y-direction from a position that overlaps with the global bit line GBLo when viewed in the Z-direction to a position that overlaps with the bit line BL. In addition, a via-contact electrode c0o (FIG. 3) extending in the Z-direction is disposed at a position that overlaps with both the bit line BL and the wiring m0o when viewed in the Z-direction. Furthermore, a via-contact electrode c1o extending in the Z-direction is disposed at a position that overlaps with both the global bit line GBLo and the wiring m0o when viewed in the Z-direction. The wiring m0o is electrically connected to the bit line BL via the via-contact electrode c0o and electrically connected to the global bit line GBLo via the via-contact electrode c1o.

Note that in the illustrated example, a width in the Y-direction of the wiring m0o is larger than a width in the Y-direction of the wiring m0e.

### [Manufacturing Method]

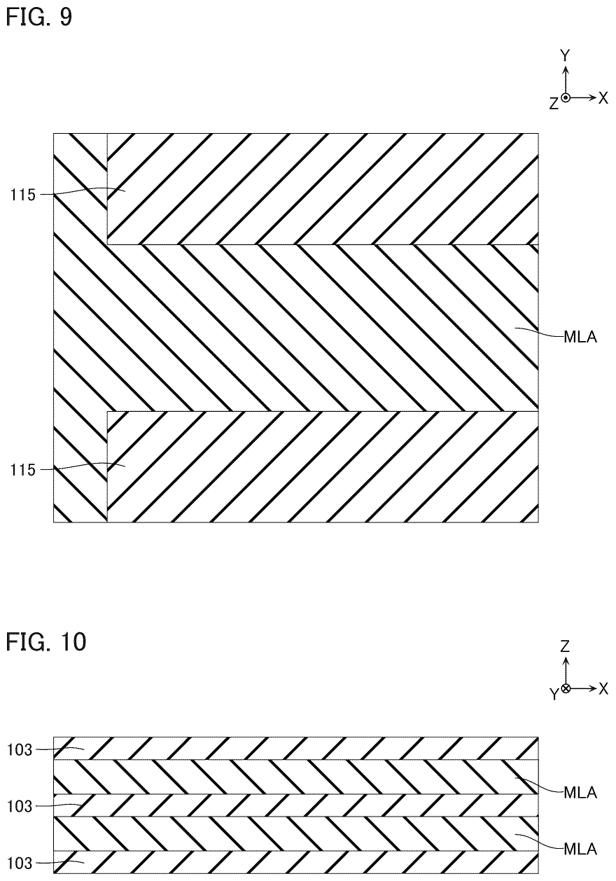

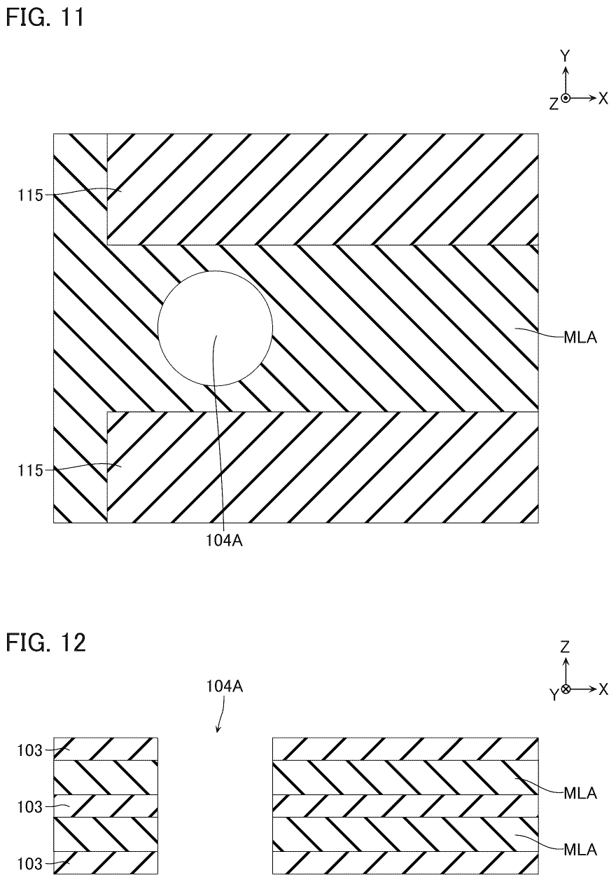

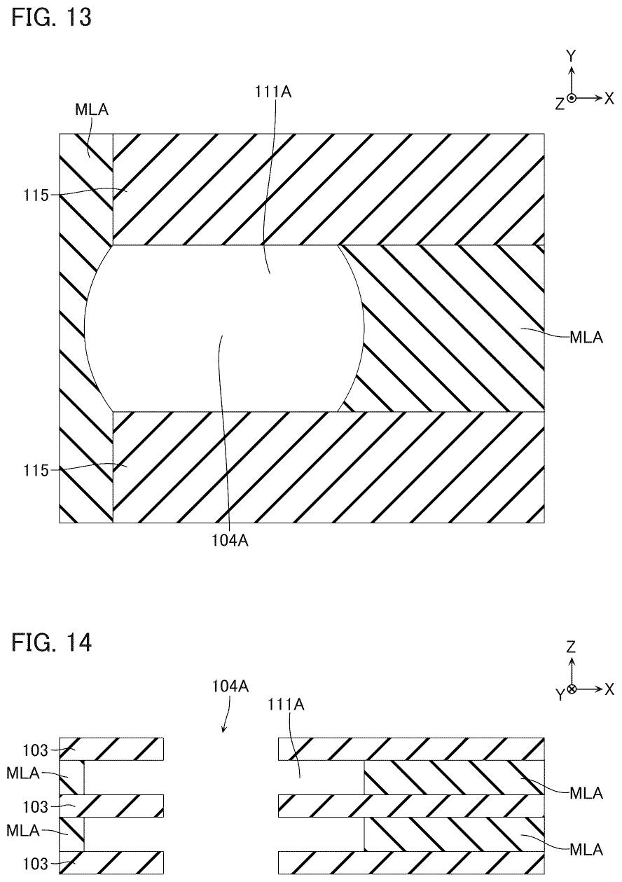

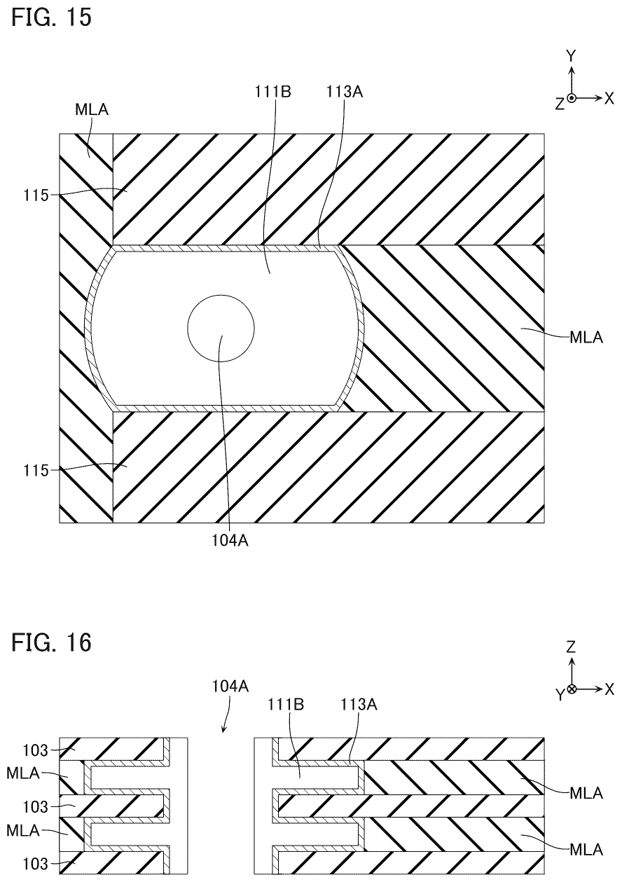

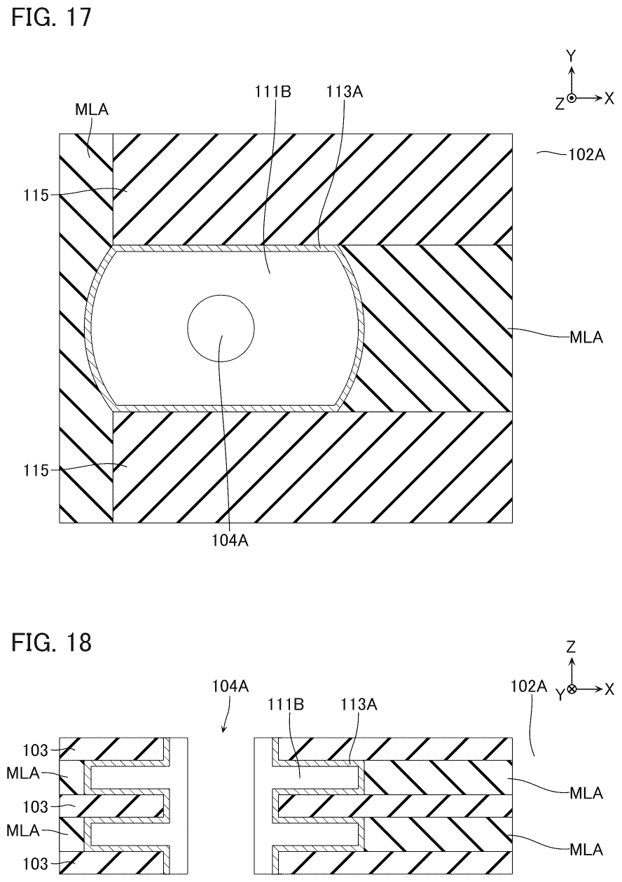

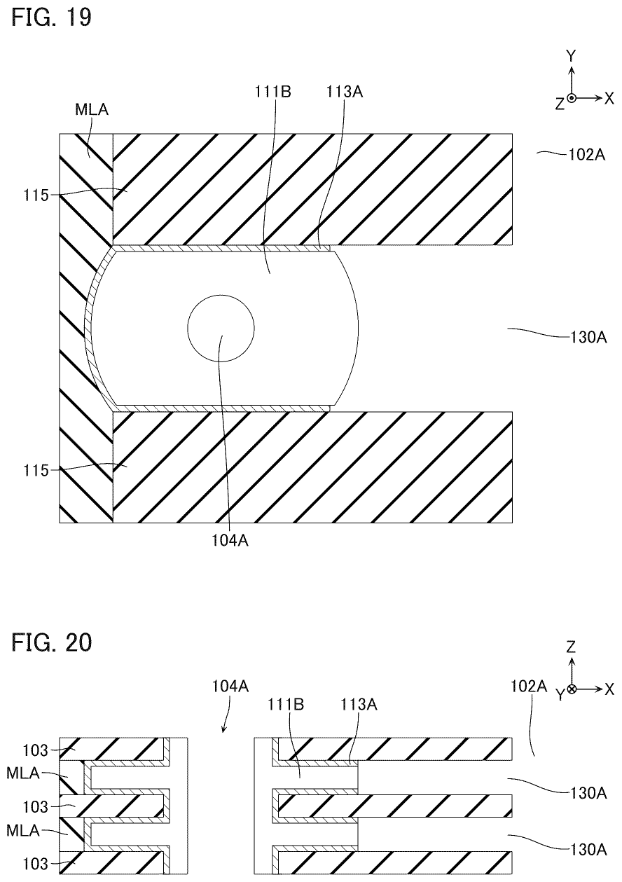

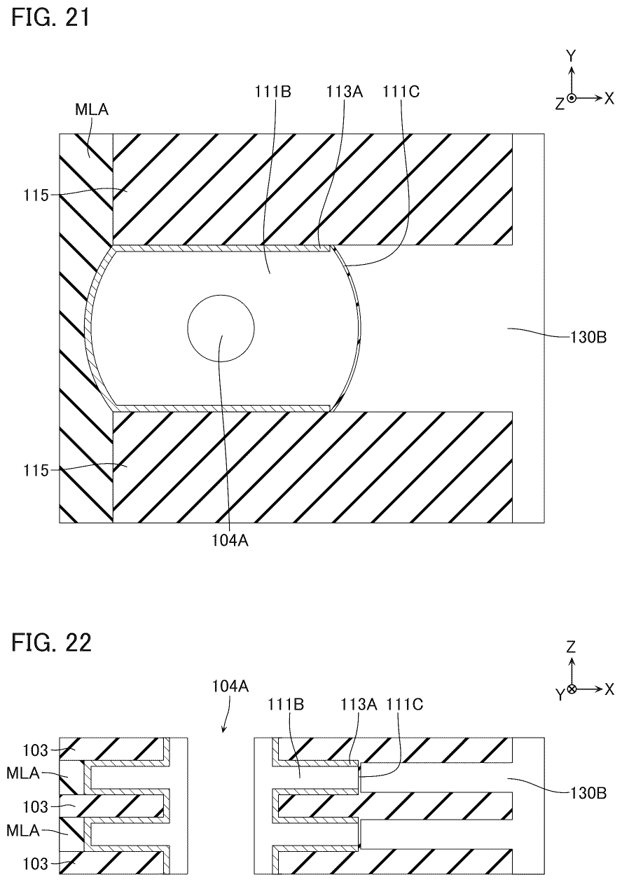

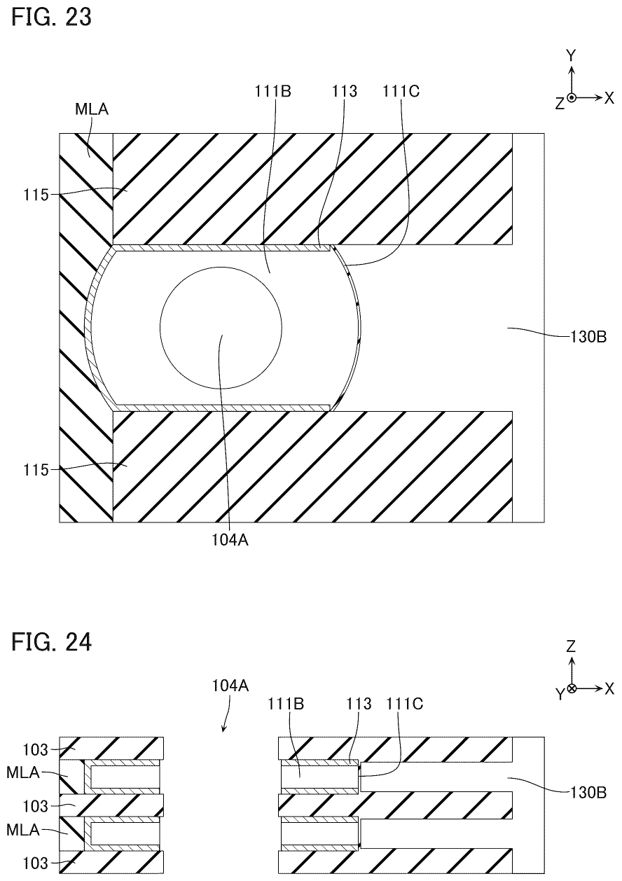

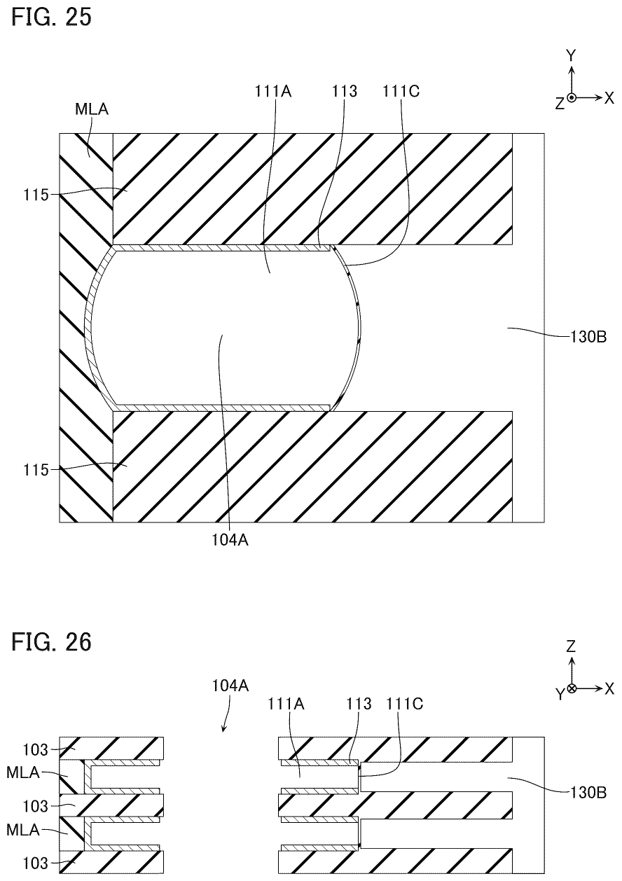

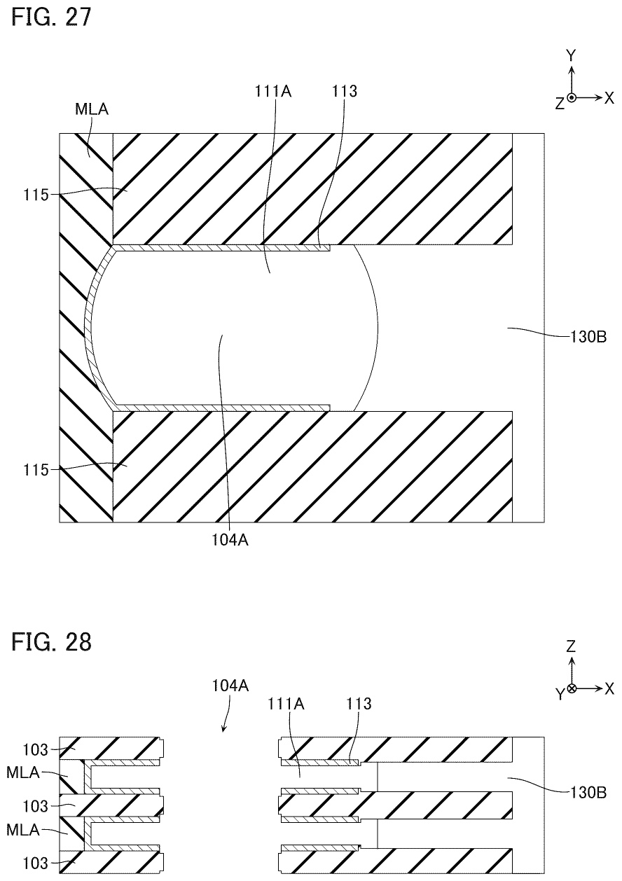

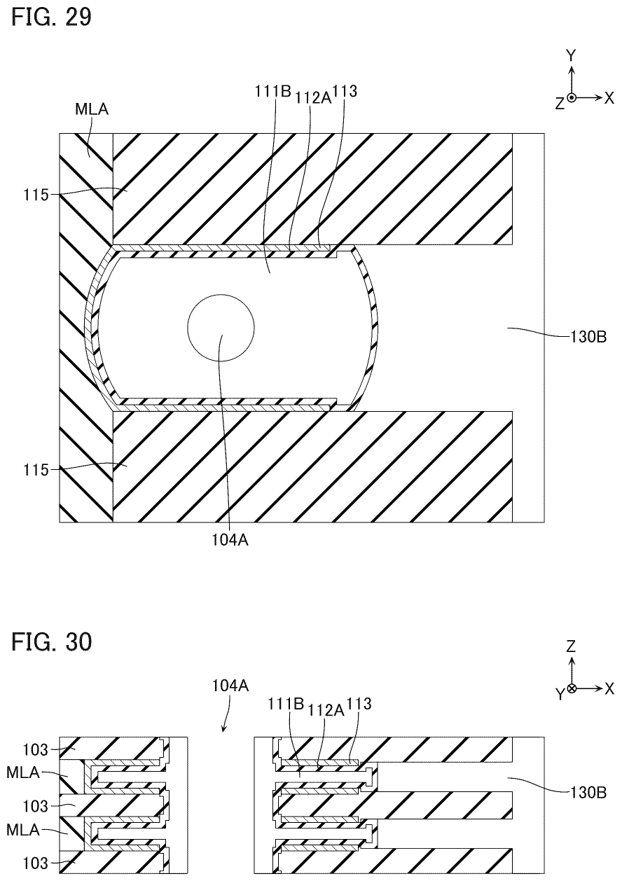

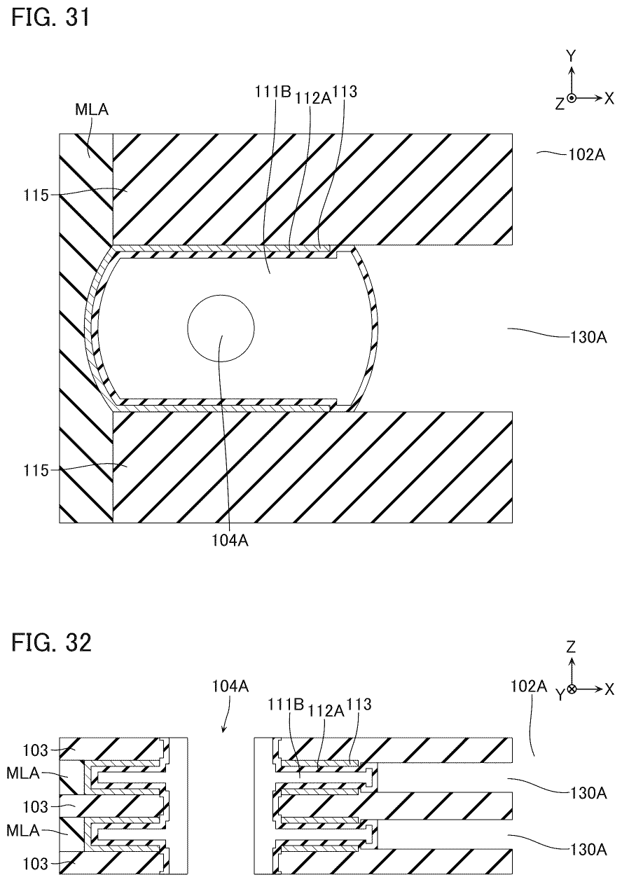

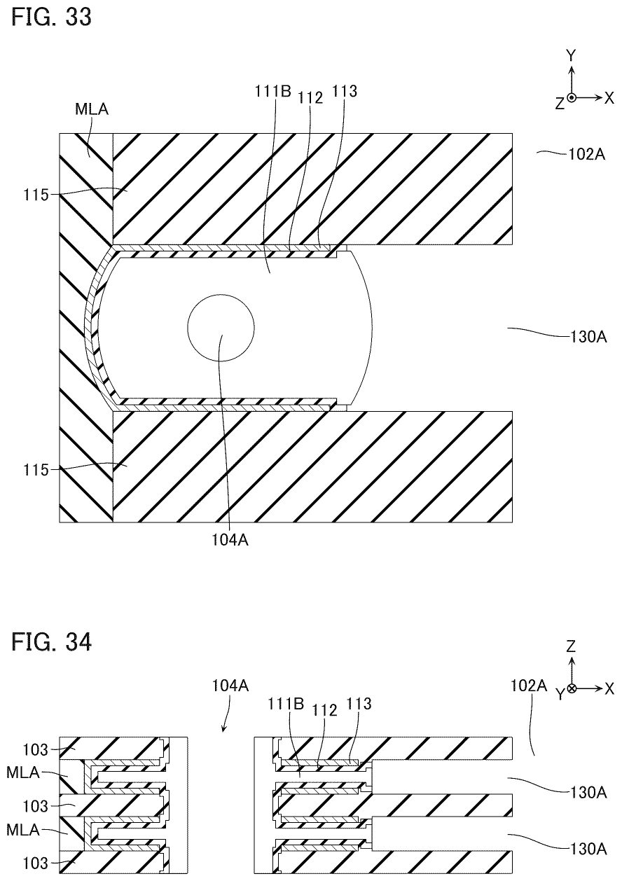

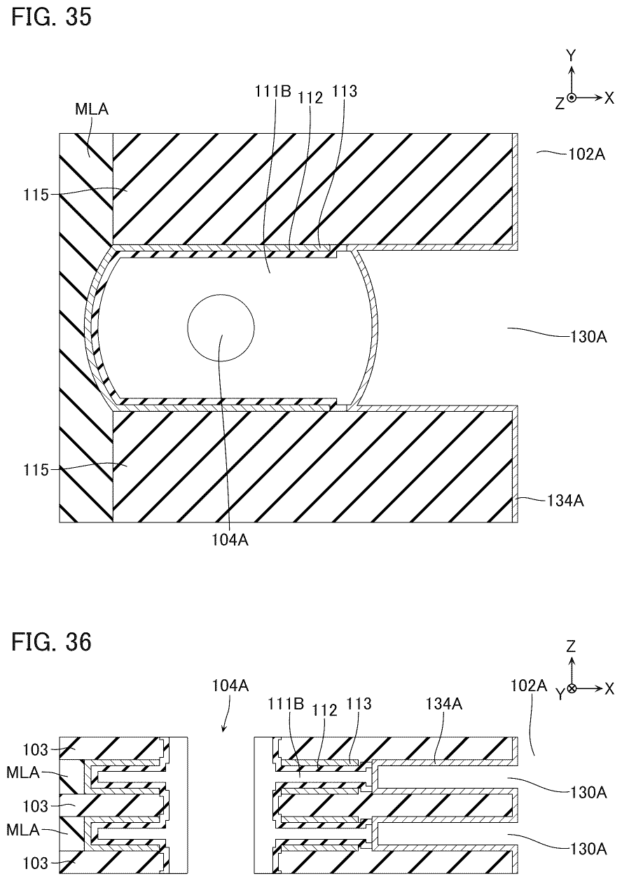

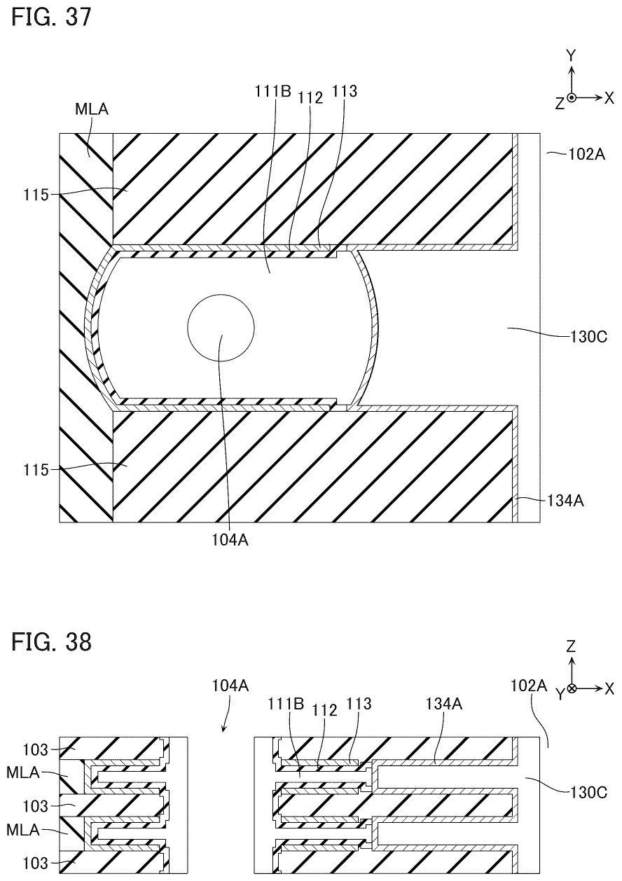

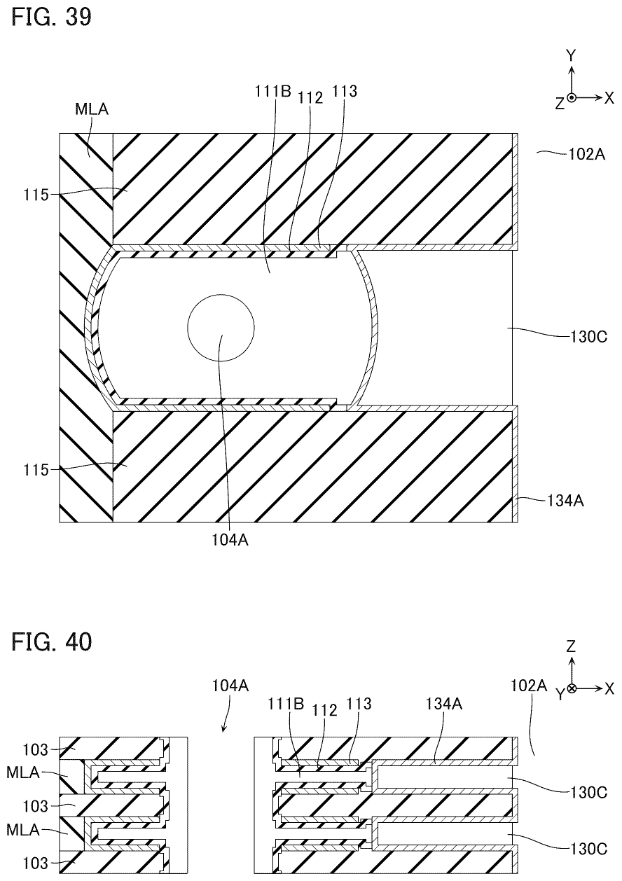

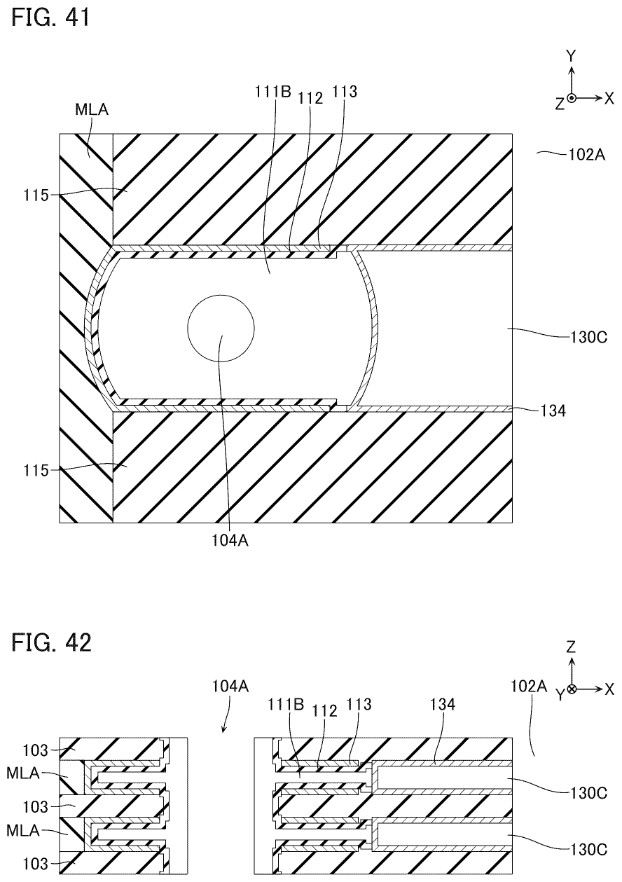

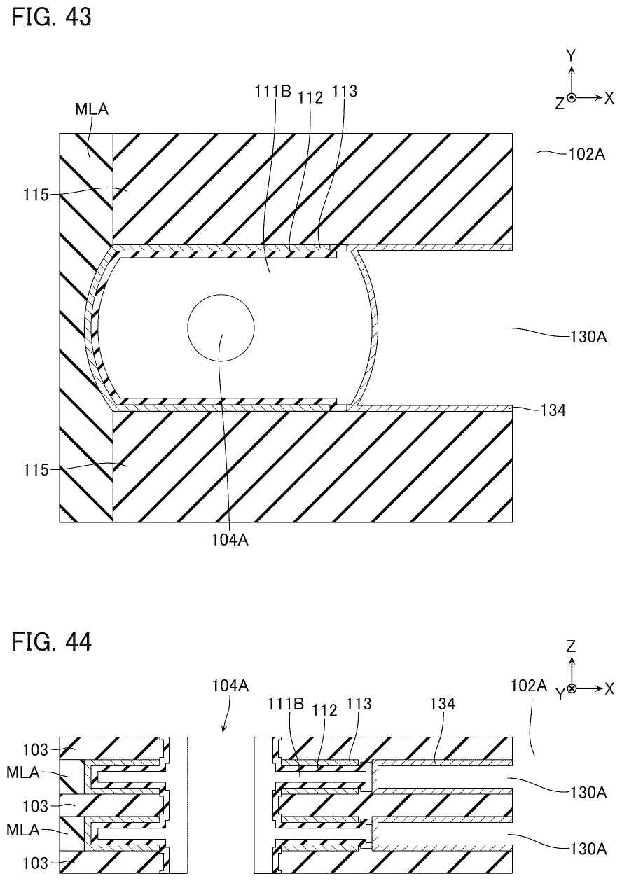

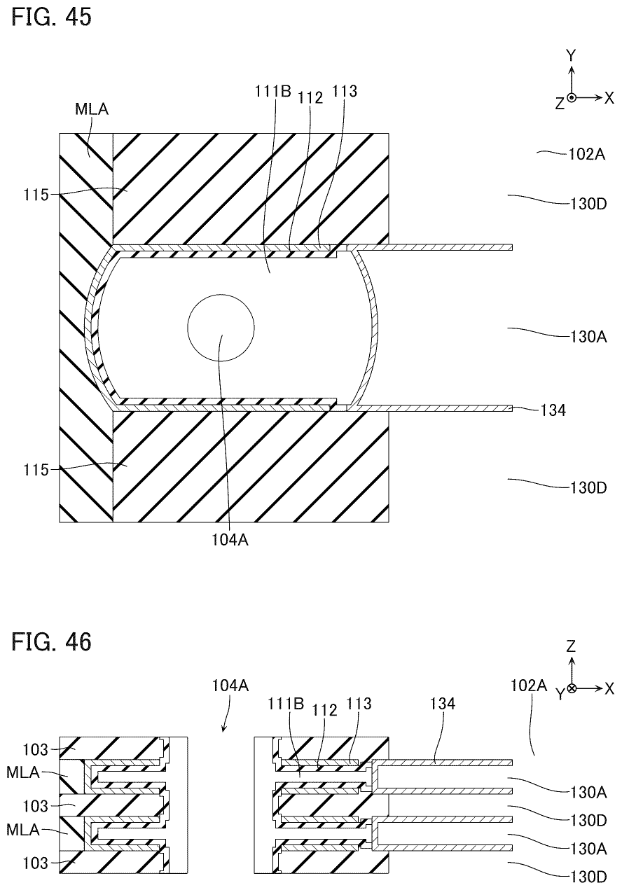

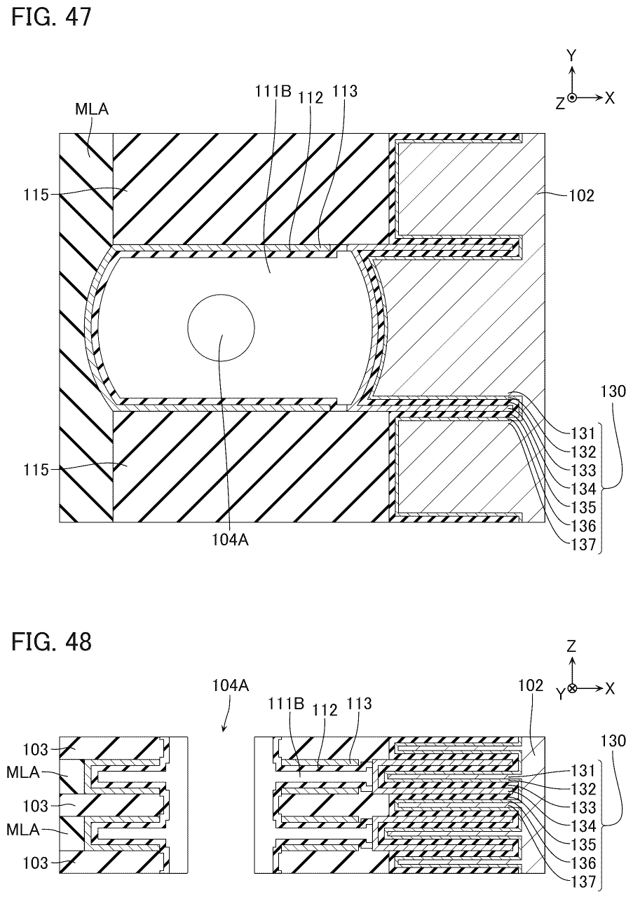

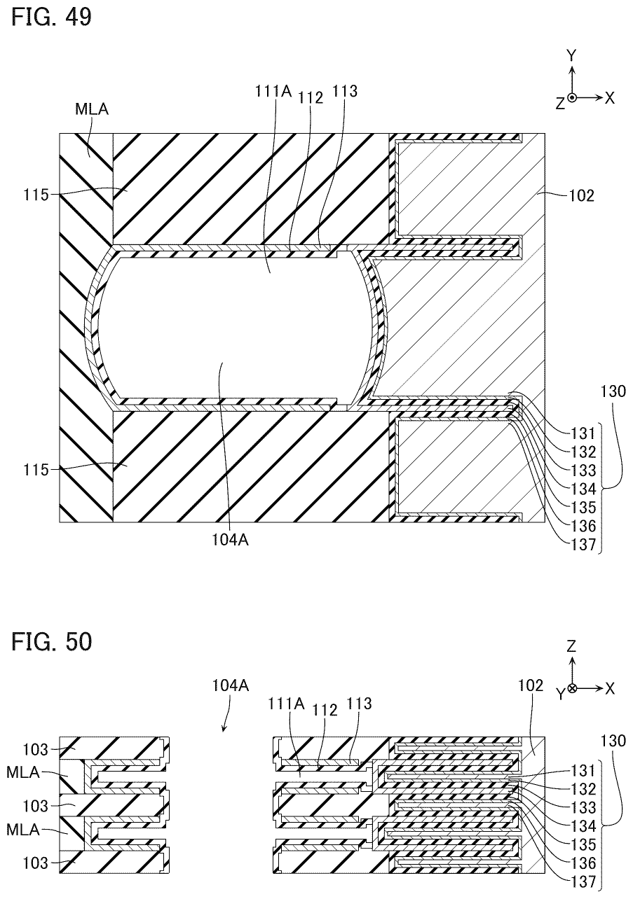

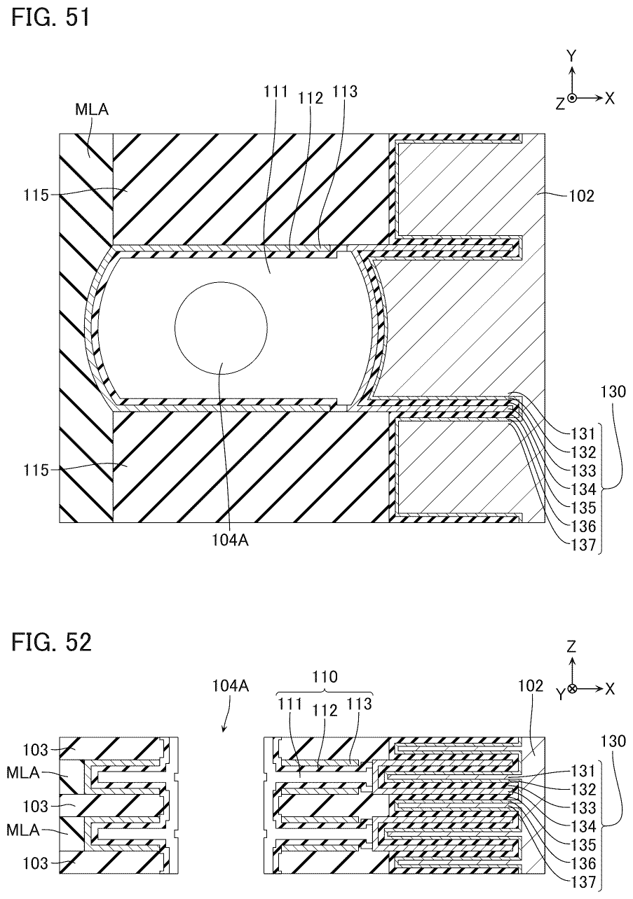

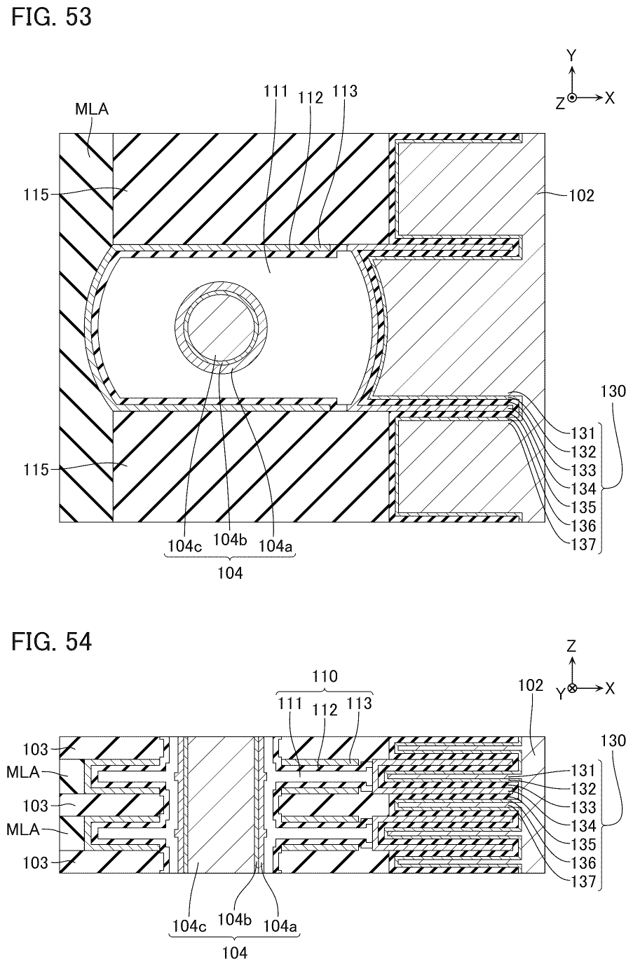

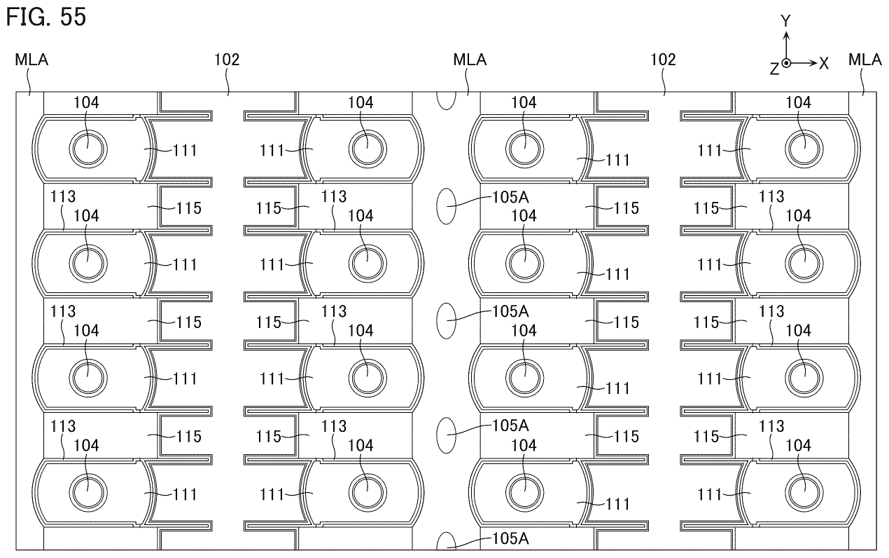

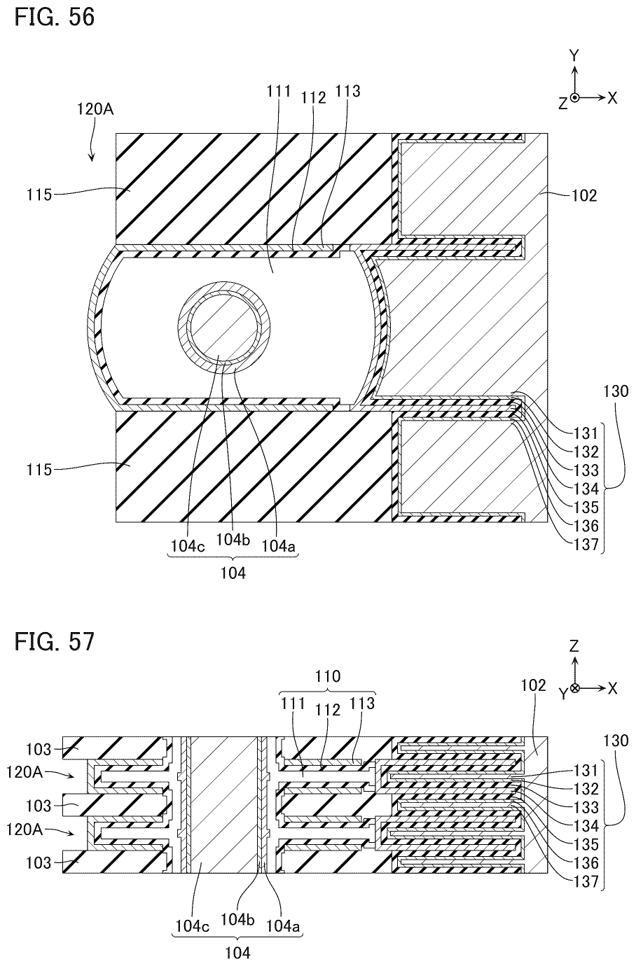

FIG. 9 to FIG. 57 are schematic cross-sectional views for describing the manufacturing method of the semiconductor memory device according to the first embodiment. FIG. 9, FIG. 11, FIG. 13, FIG. 15, FIG. 17, FIG. 19, FIG. 21, FIG. 23, FIG. 25, FIG. 27, FIG. 29, FIG. 31, FIG. 33, FIG. 35, FIG. 37, FIG. 39, FIG. 41, FIG. 43, FIG. 45, FIG. 47, FIG. 49, FIG. 51, and FIG. 56 illustrate a cross-sectional surface corresponding to FIG. 7. FIG. 10, FIG. 12, FIG. 14, FIG. 16, FIG. 18, FIG. 20, FIG. 22, FIG. 24, FIG. 26, FIG. 28, FIG. 30, FIG. 32, FIG. 34, FIG. 36, FIG. 38, FIG. 40, FIG. 42, FIG. 44, FIG. 46, FIG. 48, FIG. 50, FIG. 52, FIG. 54, and FIG. 57 illustrate a cross-sectional surface corresponding to FIG. 8. FIG. 55 illustrates a cross-sectional surface corresponding to FIG. 5.

In the manufacturing method, for example, as illustrated in FIG. 10, a plurality of insulating layers 103 and a plurality of sacrifice layers MLA are alternately formed. The sacrifice layer MLA contains, for example, silicon nitride (Si₃N₄) or the like. This process is performed by, for example, Chemical Vapor Deposition (CVD) or the like.

Next, for example, as illustrated in FIG. 9, the insulating members 115 are formed. In this process, for example, openings are formed at positions corresponding to the insulating members 115. The openings extend in the Z-direction and penetrate the plurality of insulating layers 103 and the plurality of sacrifice layers MLA arranged in the Z-direction. This process is performed by, for example, Reactive Ion Etching (RIE) or the like. After the openings are formed, the insulating members 115 are formed. This process is performed by, for example, CVD or the like.

Next, for example, as illustrated in FIG. 11 and FIG. 12, an opening 104A is formed at a position corresponding to the via wiring 104. As illustrated in FIG. 12, the opening 104A extends in the Z-direction and penetrates the plurality of insulating layers 103 and the plurality of sacrifice layers MLA arranged in the Z-direction. This process is performed by, for example, RIE or the like.

Next, for example, as illustrated in FIG. 13 and FIG. 14, an opening 111A is formed at a position corresponding to the semiconductor layer 111. Parts of upper surfaces and parts of lower surfaces of the insulating layers 103, parts of side surfaces in the X-direction of the sacrifice layers MLA, and parts of side surfaces in the Y-direction of the insulating members 115 are exposed inside the opening 111A. In this process, for example, parts of the sacrifice layers MLA are selectively removed via the opening 104A. This process is performed by, for example, wet etching or the like. For example, as illustrated in FIG. 13, side surfaces in the X-direction of the opening 111A may form curved lines when viewed in the Z-direction. For example, the opening 111A may have a length in the X-direction that differs depending on the position in the Y-direction. For example, the length in the X-direction of the opening 111A at a position close to the insulating member 115 may be shorter than the length in the X-direction of the opening 111A at a position far from the insulating member 115.

Next, for example, as illustrated in FIG. 15 and FIG. 16, a conductive layer 113A and a sacrifice layer 111B of, for example, silicon (Si) are formed inside the opening 111A and the opening 104A. The conductive layer 113A is formed on parts of the upper surfaces and parts of the lower surfaces of the insulating layers 103, surfaces of the insulating layers 103 exposed to the opening 104A, parts of the side surfaces in the X-direction of the sacrifice layers MLA, and parts of the side surfaces in the Y-direction of the insulating members 115. The opening 111A is filled with the sacrifice layer 111B, and the opening 104A is not filled with the sacrifice layer 111B. This process is performed by, for example, CVD or the like. Although the illustration is omitted, after the conductive layer 113A and the sacrifice layer 111B are formed, an upper portion of the opening 104A is closed by an insulating layer or the like.

Next, for example, as illustrated in FIG. 17 and FIG. 18, an opening 102A is formed at a position corresponding to the conductive member 102. The opening 102A extends in the Y-direction and the Z-direction, penetrates the plurality of insulating layers 103 and the plurality of sacrifice layers MLA arranged in the Z-direction and the insulating members 115, and separates these configurations in the X-direction. This process is performed by, for example, RIE or the like.

Next, for example, as illustrated in FIG. 19 and FIG. 20, openings 130A are formed at positions corresponding to the capacitor structure 130. In this process, the sacrifice layers MLA are removed via the opening 102A. A part of the conductive layer 113A, which covers a side surface on one side in the X-direction (a side surface on an opening 102A side) of the sacrifice layer 111B, is removed. In this process, the side surface in the X-direction of the sacrifice layer 111B is exposed inside the opening 102A. This process is performed by, for example, wet etching or the like.

Next, for example, as illustrated in FIG. 21 and FIG. 22, an oxidation process is performed on the sacrifice layer 111B via the opening 102A and the openings 130A to form an insulating layer 111C. In addition, the opening 102A and the openings 130A are filled with a sacrifice layer 130B of, for example, silicon (Si). This process is performed by, for example, CVD or the like.

Next, for example, as illustrated in FIG. 23 and FIG. 24, the conductive layer 113 is formed. In this process, for example, a part of the sacrifice layer 111B, which is disposed on an inner peripheral surface of the opening 104A, is removed. Next, a part of the conductive layer 113A, which is disposed on the inner peripheral surface of the opening 104A, is removed, and the conductive layer 113A is separated in the Z-direction. This process is performed by, for example, wet etching or the like.

Next, for example, as illustrated in FIG. 25 and FIG. 26, the sacrifice layer 111B is removed. This process is performed by, for example, wet etching or the like.

Next, for example, as illustrated in FIG. 27 and FIG. 28, the insulating layer 111C and a part of the sacrifice layer 130B are removed. This process is performed by, for example, wet etching or the like.

Next, for example, as illustrated in FIG. 29 and FIG. 30, an insulating layer 112A and a sacrifice layer 111B are formed inside the opening 111A and the opening 104A. The insulating layer 112A is formed on an upper surface and a lower surface of the conductive layer 113, a surface of the conductive layer 113 exposed to the opening 111A, parts of the upper surfaces and parts of the lower surfaces of the insulating layers 103, surfaces of the insulating layers 103 exposed to the opening 104A, a part of a side surface in the X-direction of the sacrifice layer 130B, and parts of the side surfaces in the Y-direction of the insulating members 115. The opening 111A is filled with the sacrifice layer 111B, and the opening 104A is not filled with the sacrifice layer 111B. This process is performed by, for example, CVD or the like. Although the illustration is omitted, after the insulating layer 112A and the sacrifice layer 111B are formed, the upper portion of the opening 104A is closed by an insulating layer or the like.

Next, for example, as illustrated in FIG. 31 and FIG. 32, the sacrifice layer 130B is removed. This process is performed by, for example, wet etching or the like.

Next, for example, as illustrated in FIG. 33 and FIG. 34, the insulating layer 112 is formed. In this process, a part of the insulating layer 112A, which covers a side surface on one side in the X-direction (a side surface on the opening 102A side) of the sacrifice layer 111B, is removed via the opening 102A and the openings 130A. In this process, the side surface in the X-direction of the sacrifice layer 111B is exposed inside the opening 102A. This process is performed by, for example, wet etching or the like.

Next, for example, as illustrated in FIG. 35 and FIG. 36, a conductive layer 134A is formed on the side surface on one side in the X-direction (the side surface on the opening 102A side) of the sacrifice layer 111B, side surfaces on one side in the X-direction (the opening 102A side) and both side surfaces in the Y-direction of the insulating members 115, and the upper surfaces, the lower surfaces, and the side surfaces on one side in the X-direction (the opening 102A side) of the insulating layers 103 via the opening 102A and the openings 130A. This process is performed by, for example, Atomic Layer Deposition (ALD) or the like.

Next, for example, as illustrated in FIG. 37 and FIG. 38, a sacrifice layer 130C of silicon (Si) or the like is formed inside the opening 102A. The openings 130A are filled with the sacrifice layer 130C, and the opening 102A is not filled with the sacrifice layer 130C. This process is performed by, for example, CVD or the like.

Next, for example, as illustrated in FIG. 39 and FIG. 40, a part of the sacrifice layer 130C is removed via the opening 102A. In this process, for example, a part of the conductive layer 134A, which is disposed on the side surfaces in the X-direction of the insulating members 115 and the insulating layers 103, is exposed. This process is performed by, for example, wet etching or the like.

Next, for example, as illustrated in FIG. 41 and FIG. 42, the conductive layer 134 is formed. In this process, for example, a part of the conductive layer 134A, which is disposed on the side surfaces in the X-direction of the insulating members 115 and the insulating layers 103, is removed, and the conductive layer 134A is separated in the Y-direction and the Z-direction. This process is performed by, for example, wet etching or the like.

Next, for example, as illustrated in FIG. 43 and FIG. 44, the sacrifice layers 130C are removed. This process is performed by, for example, wet etching or the like.

Next, for example, as illustrated in FIG. 45 and FIG. 46, parts of the insulating members 115 and parts of the insulating layers 103 are removed via the opening 102A to form openings 130D. In the illustrated example, regions inside the conductive layer 134 are indicated as the openings 130A, and regions outside the conductive layer 134 are indicated as the openings 130D. In this process, the insulating members 115 and the insulating layers 103 are removed to an extent that the conductive layer 113 is not exposed to the openings 130D. This process is performed by, for example, wet etching or the like.

Next, for example, as illustrated in FIG. 47 and FIG. 48, the insulating layers 133, 135, the conductive layers 132, 136, and the conductive layers 131, 137, and the conductive member 102 are formed on an upper surface, a lower surface, a side surface on one side in the X-direction (a side surface on the opening 102A side), and both side surfaces in the Y-direction of the conductive layer 134 via the openings 130A, the openings 130D, and the opening 102A. This process is performed by, for example, CVD or the like.

Next, for example, as illustrated in FIG. 49 and FIG. 50, the sacrifice layer 111B is removed. This process is performed by, for example, wet etching or the like.

Next, for example, as illustrated in FIG. 51 and FIG. 52, the semiconductor layer 111 is formed inside the opening 111A and the opening 104A. The opening 111A is filled with the semiconductor layer 111. The opening 104A is not filled with the semiconductor layer 111. This process is performed by, for example, ALD or the like.

Next, for example, as illustrated in FIG. 53 and FIG. 54, the via wiring 104 is formed inside the opening 104A. This process is performed by, for example, ALD and CVD.

Next, for example, as illustrated in FIG. 55, openings 105A are formed at positions corresponding to the insulating members 105. The openings 105A extend in the Z-direction and penetrate the plurality of insulating layers 103 and the plurality of sacrifice layers MLA arranged in the Z-direction. This process is performed by, for example, RIE or the like.

Next, for example, as illustrated in FIG. 56 and FIG. 57, openings 120A are formed at positions corresponding to conductive layers 120. Parts of the upper surfaces and parts of the lower surfaces of the insulating layers 103, a side surface in the X-direction of the conductive layer 113, and the side surfaces in the X-direction of the insulating members 115 are exposed inside the openings 120A. In this process, for example, the sacrifice layers MLA are selectively removed via the openings 105A. This process is performed by, for example, wet etching or the like.

Then, for example, as illustrated in FIG. 7 and FIG. 8, the conductive layers 120 are formed inside the openings 120A. This process is performed by, for example, CVD or the like.

### [Effects]

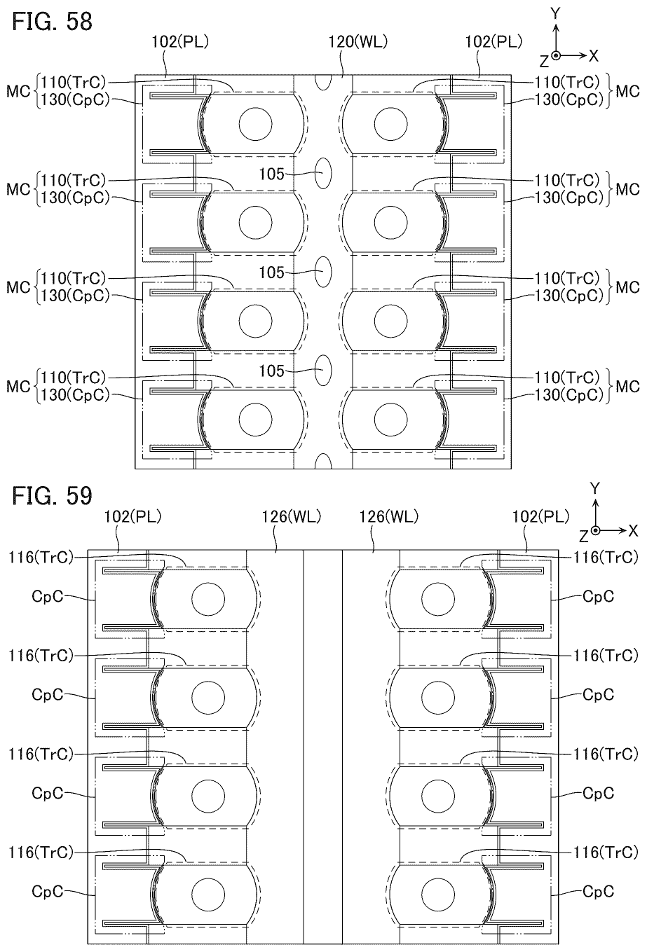

Next, effects of the semiconductor memory device according to the first embodiment are described with reference to FIG. 58 and FIG. 59. FIG. 58 and FIG. 59 are schematic X-Y cross-sectional views for describing the effects of the semiconductor memory device according to the first embodiment. FIG. 58 illustrates a configuration of a part of the semiconductor memory device according to the first embodiment. FIG. 59 illustrates a configuration of a part of a semiconductor memory device according to a comparative example.

As described above, in the memory layer ML according to the first embodiment (FIG. 58), one conductive layer 120 is disposed between two conductive members 102 adjacent in the X-direction. Each of both side surfaces in the X-direction of the conductive layer 120 is connected to a plurality of transistor structures 110 arranged in the Y-direction.

On the other hand, as illustrated in FIG. 59, in the memory layer ML0 according to the comparative example, two conductive layers 126 spaced in the X-direction are disposed between two conductive members 102 adjacent in the X-direction. These two conductive layers 126 are electrically independent from one another and function as separate word lines WL. Each of side surfaces on one side in the X-direction (the conductive member 102 side) of these two conductive layers 126 is connected to a plurality of transistor structures 116 arranged in the Y-direction. Meanwhile, side surfaces on the other side in the X-direction (a side opposite to the conductive members 102) of the two conductive layers 126 are not connected to any transistor structure 116.

The transistor structure 116 includes a semiconductor layer that is electrically connected to the via wiring 104 and functions as a channel region of the transistor and a gate electrode of the transistor that is opposed to this semiconductor layer and electrically connected to the conductive layer 126.

Here, in the first embodiment, one conductive layer 120 (FIG. 58) is disposed between two conductive members 102 adjacent in the X-direction instead of two conductive layers 126 (FIG. 59). Therefore, in the X-direction, a wiring width for an amount of approximately one conductive layer 126 can be reduced. A width for an amount of an insulating layer between two conductive layers 126 can also be reduced. This allows achieving a high integration of the memory cell array MCA.

Furthermore, in the transistor structure 110 according to the embodiment, the conductive layer 113 is opposed to the upper surface, the lower surface, and both side surfaces in the Y-direction of the semiconductor layer 111.

In such a configuration, interference of electric fields occurring between a plurality of semiconductor layers 111 arranged in the Z-direction can be reduced. Therefore, even when the high integration in the Z-direction of the memory cell array MCA is achieved, the semiconductor layers 111 can be preferably controlled in the ON state or the OFF state, allowing the semiconductor memory device that preferably operates to be provided.

When the transistor TrC is turned ON, a channel is formed on the upper surface, the lower surface, and both side surfaces in the Y-direction of the semiconductor layer 111. Therefore, an ON current of the transistor TrC can be relatively large. This allows achieving the speed-up and the stabilization of the operation.

In addition, in the embodiment, the conductive layer 120 functioning as the word line WL is disposed on a side opposite to the plate line PL with respect to the transistor structures 110 and disposed at a position that does not overlap with the transistor structures 110 when viewed in the Z-direction. Therefore, the conductive layers 120 and the transistor structures 110 can be formed independently and can be relatively easily manufactured. Furthermore, wiring resistance of the conductive layers 120 can be a relatively small value while reducing a width in the Z-direction of the memory layer ML.

### Second Embodiment

As described with reference to FIG. 55 to FIG. 57, in manufacturing the semiconductor memory device according to the first embodiment, the openings 105A that penetrate the plurality of insulating layers 103 and the plurality of sacrifice layers MLA arranged in the Z-direction are formed, and the removal of the sacrifice layers MLA and the formation of the conductive layers 120 are performed via the openings 105A. After the conductive layers 120 are formed, the insulating members 105 are formed inside the openings 105A.

Here, the position, shape, size, and the like of the opening 105A are adjustable as appropriate. Therefore, the position, shape, size, and the like of a configuration corresponding to the insulating member 105 are also adjustable as appropriate. As the second embodiment to the fourth embodiment, other exemplary configurations of the insulating member 105 are described below.

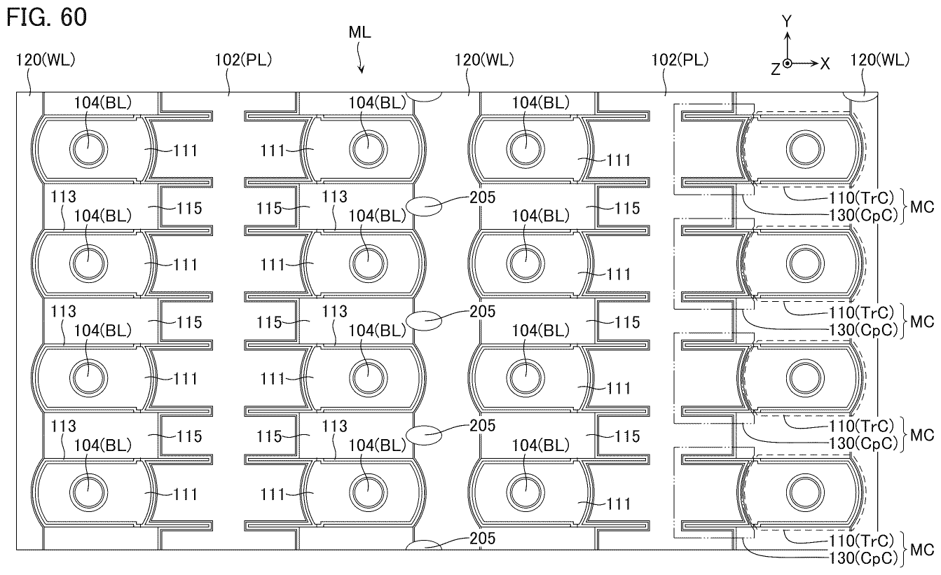

First, a semiconductor memory device according to the second embodiment is described with reference to FIG. 60. FIG. 60 is a schematic X-Y cross-sectional view illustrating a configuration of a part of the semiconductor memory device. In the following description, configurations similar to those of the first embodiment are attached by the same reference numerals and their descriptions are omitted.

The semiconductor memory device according to the second embodiment is basically configured similarly to the semiconductor memory device according to the first embodiment.

However, the semiconductor memory device according to the second embodiment includes a plurality of insulating members 205 instead of the plurality of insulating members 105. The insulating members 205 are basically configured similarly to the insulating members 105. However, a position in the X-direction of one of the insulating members 205 is disposed on one side in the X-direction (a negative side in the X-direction in the illustrated example) with respect to the middle position in the X-direction of the conductive layer 120. Each of middle positions in the X-direction of the insulating members 205 is disposed on one side in the X-direction (a negative side in the X-direction in the illustrated example) with respect to the middle position in the X-direction of the conductive layer 120.

As described with reference to FIG. 5, an outer peripheral surface of the insulating member 105 according to the first embodiment is surrounded by the conductive layer 120 over the whole circumference and connected to the conductive layer 120. On the other hand, in the example of FIG. 60, an outer peripheral surface of the insulating member 205 is surrounded by the conductive layer 120 and the insulating member 115 and connected to the conductive layer 120 and the insulating member 115.

### Third Embodiment

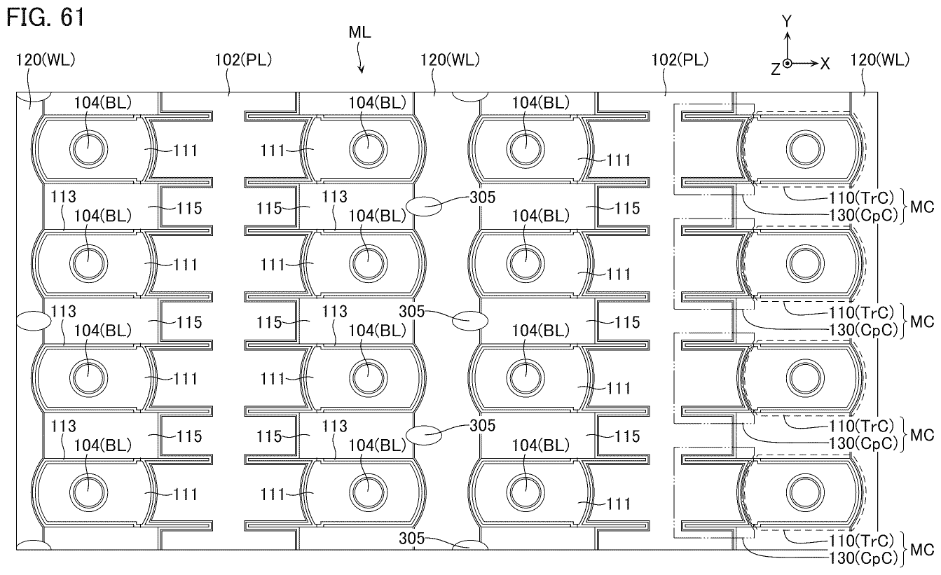

Next, a semiconductor memory device according to the third embodiment is described with reference to FIG. 61. FIG. 61 is a schematic X-Y cross-sectional view illustrating a configuration of a part of the semiconductor memory device. In the following description, configurations similar to those of the first embodiment are attached by the same reference numerals and their descriptions are omitted.

The semiconductor memory device according to the third embodiment is basically configured similarly to the semiconductor memory device according to the first embodiment.

However, the semiconductor memory device according to the third embodiment includes a plurality of insulating members 305 instead of the plurality of insulating members 105. The insulating members 305 are basically configured similarly to the insulating members 105. However, a position in the X-direction of one of a part of the insulating members 305 (in the illustrated example, odd-numbered insulating members 305 counted from the positive side in the Y-direction) is disposed on one side in the X-direction (for example, a positive side in the X-direction) with respect to the middle position in the X-direction of the conductive layer 120. In addition, a position in the X-direction of one of others of the insulating members 305 (in the illustrated example, even-numbered insulating members 305 counted from the positive side in the Y-direction) is disposed on the other side in the X-direction (for example, a negative side in the X-direction) with respect to the middle position in the X-direction of the conductive layer 120.

In the example of FIG. 61, an outer peripheral surface of the insulating member 305 is surrounded by the conductive layer 120 and the insulating member 115 and connected to the conductive layer 120 and the insulating member 115.

### Fourth Embodiment

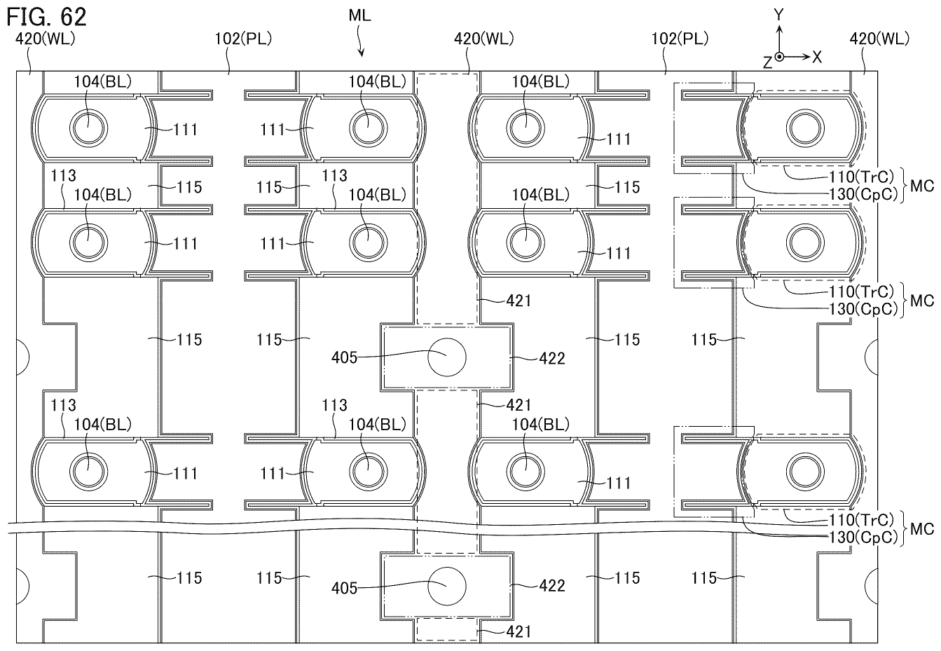

Next, a semiconductor memory device according to the fourth embodiment is described with reference to FIG. 62. FIG. 62 is a schematic X-Y cross-sectional view illustrating a configuration of a part of the semiconductor memory device. In the following description, configurations similar to those of the first embodiment are attached by the same reference numerals and their descriptions are omitted.

The semiconductor memory device according to the fourth embodiment is basically configured similarly to the semiconductor memory device according to the first embodiment.

However, the semiconductor memory device according to the fourth embodiment includes a plurality of insulating members 405 instead of the plurality of insulating members 105. The insulating members 405 are basically configured similarly to the insulating members 105. However, the number of the plurality of insulating members 105 arranged in the Y-direction is the same as the number of the plurality of insulating members 115 arranged in the Y-direction. On the other hand, the number of the plurality of insulating members 405 arranged in the Y-direction is less than the number of the plurality of insulating members 115 arranged in the Y-direction.

In addition, the semiconductor memory device according to the fourth embodiment includes conductive layers 420 instead of the conductive layers 120. The conductive layer 420 includes a plurality of parts 421 and parts 422 arranged alternately in the Y-direction. The parts 421 are configured similarly to the conductive layers 120. The parts 422 are disposed at positions corresponding to the insulating members 405. Unlike the parts 421, the parts 422 are not connected to any conductive layer 113. A width in the X-direction of the part 422 is greater than a width in the X-direction of the part 421. A width in the Y-direction of the part 422 is smaller than a width in the Y-direction of the part 421. The widths in the X-direction and the Y-direction of the part 422 are greater than respective widths in the X-direction and the Y-direction of the insulating member 405.

Here, the conductive layer 420 according to the fourth embodiment includes the parts 421 connected to the transistor structures 110 and the parts 422 at which the insulating members 405 are disposed. With such a configuration, since configurations corresponding to the insulating members 105 are not formed in the parts 421, the high integration of the memory cell array MCA can be further allowed in some cases by decreasing the width in the X-direction of the part 421.

In the example of FIG. 62, an outer peripheral surface of the insulating member 405 is surrounded by the conductive layer 420 over the whole circumference and connected to the conductive layer 420.

### Fifth Embodiment

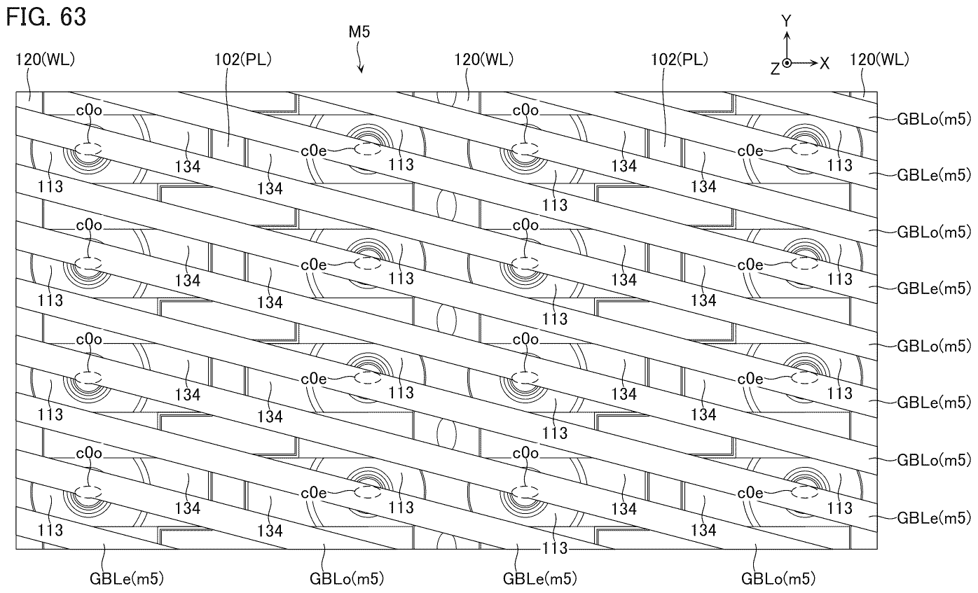

Next, a semiconductor memory device according to the fifth embodiment is described with reference to FIG. 63. FIG. 63 is a schematic plan view illustrating a configuration of a part of the semiconductor memory device. In the following description, configurations similar to those of the first embodiment are attached by the same reference numerals and their descriptions are omitted.

The semiconductor memory device according to the fifth embodiment is basically configured similarly to the semiconductor memory device according to the first embodiment.

However, the semiconductor memory device according to the fifth embodiment includes a wiring layer M5 instead of the wiring layers M0, M1.

The wiring layer M5 includes a plurality of wirings m5. These plurality of wirings m5 may include, for example, a stacked film of a barrier conductive film of, for example, titanium nitride (TiN) and a metal film of, for example, tungsten (W) or copper (Cu), or the like. At least a part of the plurality of wirings m5 function as the global bit lines GBL (FIG. 1).

Here, as described with reference to FIG. 6, each of the plurality of global bit lines GBL according to the first embodiment extends in the X-direction and is electrically connected to the plurality of via wirings 104 that approximately coincide in position in the Y-direction.

On the other hand, as illustrated in FIG. 63, each of the plurality of global bit lines GBL according to the fifth embodiment extends in a diagonal direction (a direction that does not coincide with the Y-direction or the X-direction in an X-Y plane and the X-Y cross-sectional surface) and is electrically connected to the plurality of via wirings 104 that differ in position in the Y-direction.

In the fifth embodiment, both of the global bit lines GBLo, GBLe are disposed at positions that overlap with a plurality of corresponding bit lines BL when viewed in the Z-direction. These plurality of global bit lines GBLo, GBLe are in direct contact with the via-contact electrodes c0o, c0e on their lower surfaces.

With such a configuration, the configuration corresponding to the wiring layer M0 and the plurality of via-contact electrodes c1o, c1e can be omitted. Therefore, compared with the first embodiment, a manufacturing cost can be reduced.

The semiconductor memory device according to the fifth embodiment may include the plurality of insulating members 205 (FIG. 60), the plurality of insulating members 305 (FIG. 61), or the plurality of insulating members 405 (FIG. 62) instead of the plurality of insulating members 105. When the semiconductor memory device according to the fifth embodiment includes the plurality of insulating members 405, the semiconductor memory device according to the fifth embodiment may include the conductive layers 420 (FIG. 62) instead of the conductive layers 120.

### Sixth Embodiment

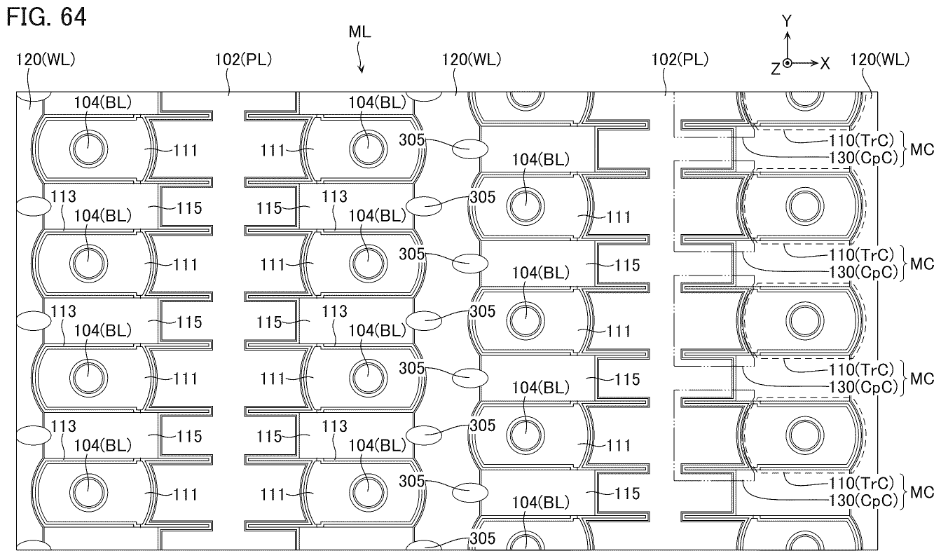

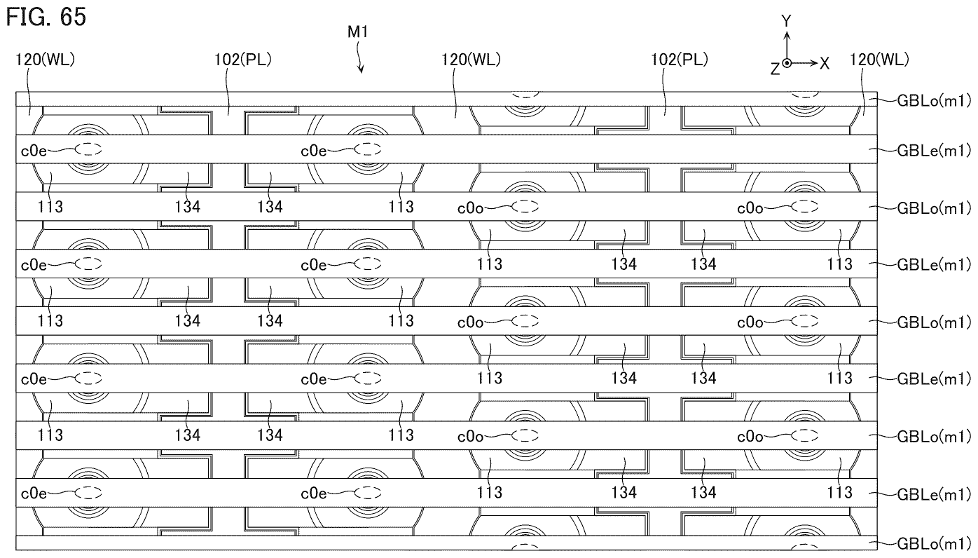

Next, a semiconductor memory device according to the sixth embodiment is described with reference to FIG. 64 and FIG. 65. FIG. 64 is a schematic X-Y cross-sectional view illustrating a configuration of a part of the semiconductor memory device. FIG. 65 is a schematic plan view illustrating a configuration of a part of the semiconductor memory device. In the following description, configurations similar to those of the third embodiment are attached by the same reference numerals and their descriptions are omitted.

The semiconductor memory device according to the sixth embodiment is basically configured similarly to the semiconductor memory device according to the third embodiment.

Here, as described with reference to FIG. 5, in the semiconductor memory device according to the first embodiment, a plurality of via wirings 104 are disposed so as to form two rows that differ in position in the X-direction between two conductive members 102 adjacent in the X-direction. In focusing on these plurality of via wirings 104, each of the positions in the Y-direction of the plurality of via wirings 104 included in the row disposed on one side in the X-direction with respect to the conductive layer 120 approximately coincides with any of the positions in the Y-direction of the plurality of via wirings 104 included in the row disposed on the other side in the X-direction with respect to the conductive layer 120.

As illustrated in FIG. 64, in the semiconductor memory device according to the sixth embodiment, a plurality of via wirings 104 are also disposed so as to form two rows that differ in position in the X-direction between two conductive members 102 adjacent in the X-direction. However, in focusing on these plurality of via wirings 104, a position in the Y-direction of one of the plurality of via wirings 104 included in one row does not coincide with any of the positions in the Y-direction of the plurality of via wirings 104 included in the other row. In focusing on these plurality of via wirings 104, each of the positions in the Y-direction of the plurality of via wirings 104 included in the row disposed on one side in the X-direction with respect to the conductive layer 120 does not coincide with any of the positions in the Y-direction of the plurality of via wirings 104 included in the row disposed on the other side in the X-direction with respect to the conductive layer 120.

For example, in the example of FIG. 64, each of the positions in the Y-direction of the plurality of via wirings 104 included in the row disposed on one side in the X-direction with respect to the conductive layer 120 approximately coincides with an intermediate position of any two via wirings 104 adjacent in the Y-direction among the plurality of via wirings 104 included in the row disposed on the other side in the X-direction with respect to the conductive layer 120. Each of the positions in the Y-direction of the plurality of via wirings 104 included in the row disposed on one side in the X-direction with respect to the conductive layer 120 is between the positions in the Y-direction of any two via wirings 104 adjacent in the Y-direction among the plurality of via wirings 104 included in the row disposed on the other side in the X-direction with respect to the conductive layer 120.

In addition, the semiconductor memory device according to the sixth embodiment does not include the wiring layer M0.

In the sixth embodiment, as illustrated in FIG. 65, both of the global bit lines GBLo, GBLe in the wiring layer M1 are disposed at positions that overlap with a plurality of corresponding bit lines BL when viewed in the Z-direction. These plurality of global bit lines GBLo, GBLe are in direct contact with the via-contact electrodes c0o, c0e on their lower surfaces.

With such a configuration, the configuration corresponding to the wiring layer M0 and the plurality of via-contact electrodes c1o, c1e can be omitted. Therefore, compared with the first embodiment, a manufacturing cost can be reduced.

### Seventh Embodiment

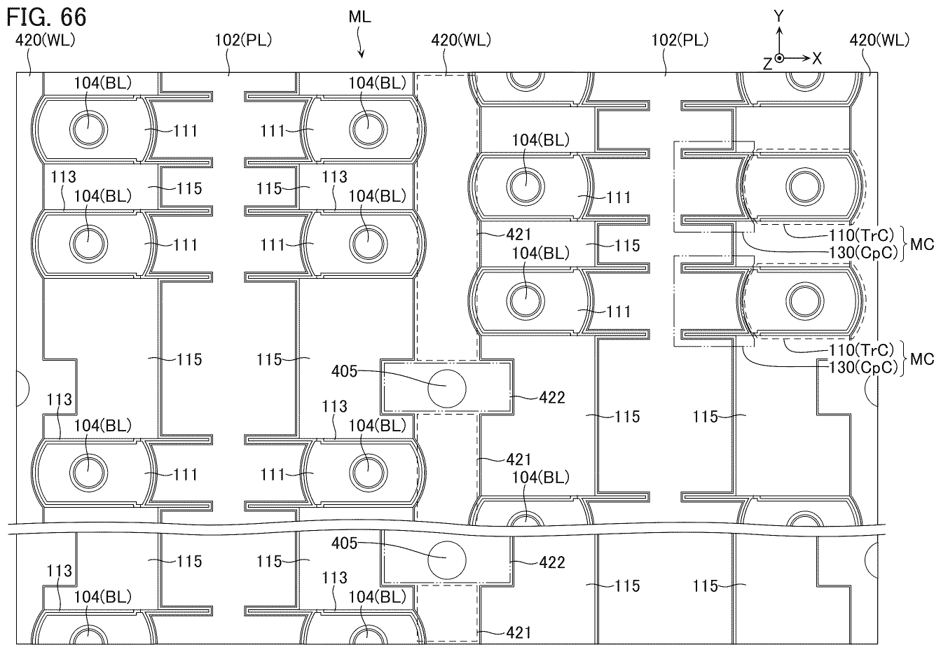

Next, a semiconductor memory device according to the seventh embodiment is described with reference to FIG. 66. FIG. 66 is a schematic X-Y cross-sectional view illustrating a configuration of a part of the semiconductor memory device. In the following description, configurations similar to those of the sixth embodiment are attached by the same reference numerals and their descriptions are omitted.

The semiconductor memory device according to the seventh embodiment is basically configured similarly to the semiconductor memory device according to the sixth embodiment.

However, the semiconductor memory device according to the seventh embodiment includes the plurality of insulating members 405 described with reference to FIG. 62 instead of the plurality of insulating members 305. The number of the plurality of insulating members 405 arranged in the Y-direction is less than the number of the plurality of insulating members 115 arranged in the Y-direction.

In addition, the semiconductor memory device according to the seventh embodiment includes the conductive layers 420 described with reference to FIG. 62 instead of the conductive layers 120.

In the example of FIG. 66, an outer peripheral surface of the insulating member 405 is surrounded by the conductive layer 420 over the whole circumference and connected to the conductive layer 420.

### Eighth Embodiment

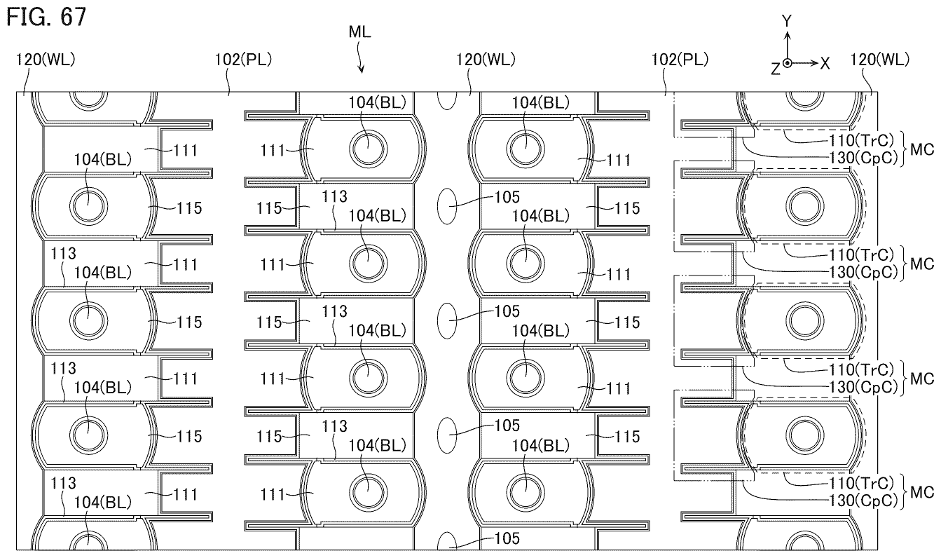

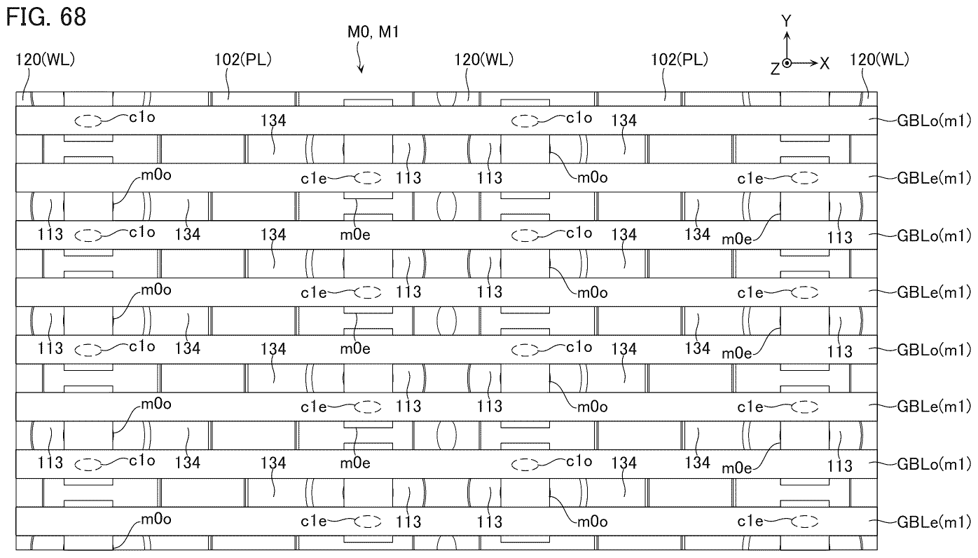

Next, a semiconductor memory device according to the eighth embodiment is described with reference to FIG. 67 and FIG. 68. FIG. 67 is a schematic X-Y cross-sectional view illustrating a configuration of a part of the semiconductor memory device. FIG. 68 is a schematic plan view illustrating a configuration of a part of the semiconductor memory device. In the following description, configurations similar to those of the third embodiment are attached by the same reference numerals and their descriptions are omitted.

The semiconductor memory device according to the eighth embodiment is basically configured similarly to the semiconductor memory device according to the first embodiment.

Here, as described with reference to FIG. 5, in the semiconductor memory device according to the first embodiment, a plurality of via wirings 104 are disposed so as to form two rows that differ in position in the X-direction between two conductive layers 120 adjacent in the X-direction. In focusing on these plurality of via wirings 104, each of the positions in the Y-direction of the plurality of via wirings 104 included in the row disposed on one side in the X-direction with respect to the conductive member 102 approximately coincides with any of the positions in the Y-direction of the plurality of via wirings 104 included in the row disposed on the other side in the X-direction with respect to the conductive member 102.

As illustrated in FIG. 67, in the semiconductor memory device according to the eighth embodiment, a plurality of via wirings 104 are also disposed so as to form two rows that differ in position in the X-direction between two conductive layers 120 adjacent in the X-direction. However, in focusing on these plurality of via wirings 104, a position in the Y-direction of one the plurality of via wirings 104 included in one row does not coincide with any of the positions in the Y-direction of the plurality of via wirings 104 included in the other row. In focusing on these plurality of via wirings 104, each of the positions in the Y-direction of the plurality of via wirings 104 included in the row disposed on one side in the X-direction with respect to the conductive member 102 does not coincide with any of the positions in the Y-direction of the plurality of via wirings 104 included in the row disposed on the other side in the X-direction with respect to the conductive member 102.

For example, in the example of FIG. 67, each of the positions in the Y-direction of the plurality of via wirings 104 included in the row disposed on one side in the X-direction with respect to the conductive member 102 approximately coincides with an intermediate position of any two via wirings 104 adjacent in the Y-direction among the plurality of via wirings 104 included in the row disposed on the other side in the X-direction with respect to the conductive member 102. Each of the positions in the Y-direction of the plurality of via wirings 104 included in the row disposed on one side in the X-direction with respect to the conductive member 102 is between the positions in the Y-direction of any two via wirings 104 adjacent in the Y-direction among the plurality of via wirings 104 included in the row disposed on the other side in the X-direction with respect to the conductive member 102.

In addition, as illustrated in FIG. 68, in the eighth embodiment, both of the global bit lines GBLo, GBLe are disposed at positions that do not overlap with a plurality of corresponding bit lines BL when viewed in the Z-direction. Furthermore, in the example of FIG. 68, a width in the Y-direction of the wiring m0e approximately coincides with a width in the Y-direction of the wiring moo.

The semiconductor memory device according to the eighth embodiment may include the plurality of insulating members 205 (FIG. 60), the plurality of insulating members 305 (FIG. 61), or the plurality of insulating members 405 (FIG. 62) instead of the plurality of insulating members 105. When the semiconductor memory device according to the eighth embodiment includes the plurality of insulating members 405, the semiconductor memory device according to the eighth embodiment may include the conductive layers 420 (FIG. 62) instead of the conductive layers 120.

### Ninth Embodiment

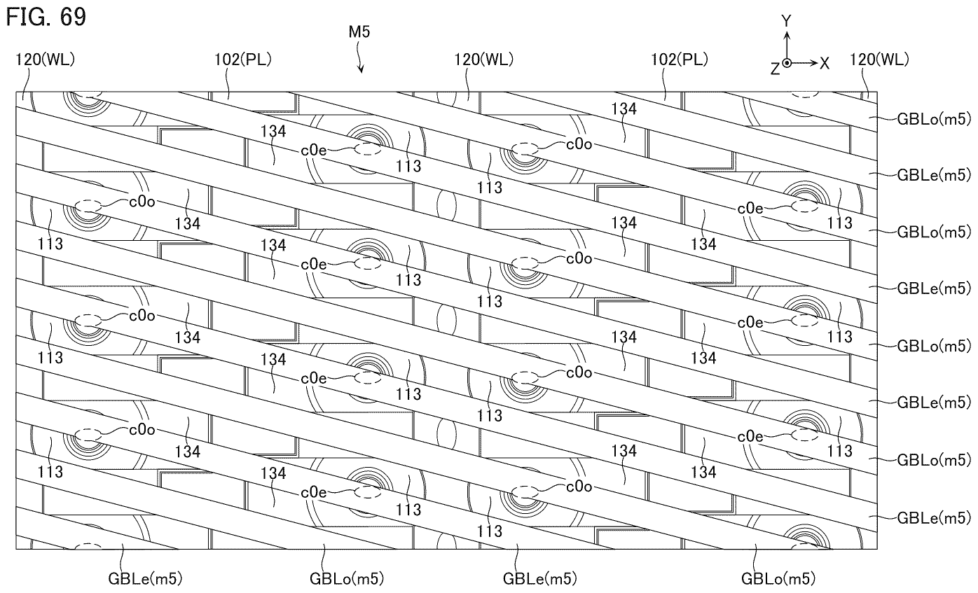

Next, a semiconductor memory device according to the ninth embodiment is described with reference to FIG. 69. FIG. 69 is a schematic plan view illustrating a configuration of a part of the semiconductor memory device. In the following description, configurations similar to those of the first embodiment are attached by the same reference numerals and their descriptions are omitted.

The semiconductor memory device according to the ninth embodiment is basically configured similarly to the semiconductor memory device according to the eighth embodiment.

However, the semiconductor memory device according to the ninth embodiment includes the wiring layer M5 described with reference to FIG. 63 instead of the wiring layers M0, M1.

In the ninth embodiment, both of the global bit lines GBLo, GBLe are disposed at positions that overlap with a plurality of corresponding bit lines BL when viewed in the Z-direction. These plurality of global bit lines GBLo, GBLe are in direct contact with the via-contact electrodes c0o, c0e on their lower surfaces.

With such a configuration, the configuration corresponding to the wiring layer M0 and the plurality of via-contact electrodes c1o, c1e can be omitted. Therefore, compared with the first embodiment, a manufacturing cost can be reduced.

The semiconductor memory device according to the ninth embodiment may include the plurality of insulating members 205 (FIG. 60), the plurality of insulating members 305 (FIG. 61), or the plurality of insulating members 405 (FIG. 62) instead of the plurality of insulating members 105. When the semiconductor memory device according to the ninth embodiment includes the plurality of insulating members 405, the semiconductor memory device according to the ninth embodiment may include the conductive layers 420 (FIG. 62) instead of the conductive layers 120.

### Tenth Embodiment

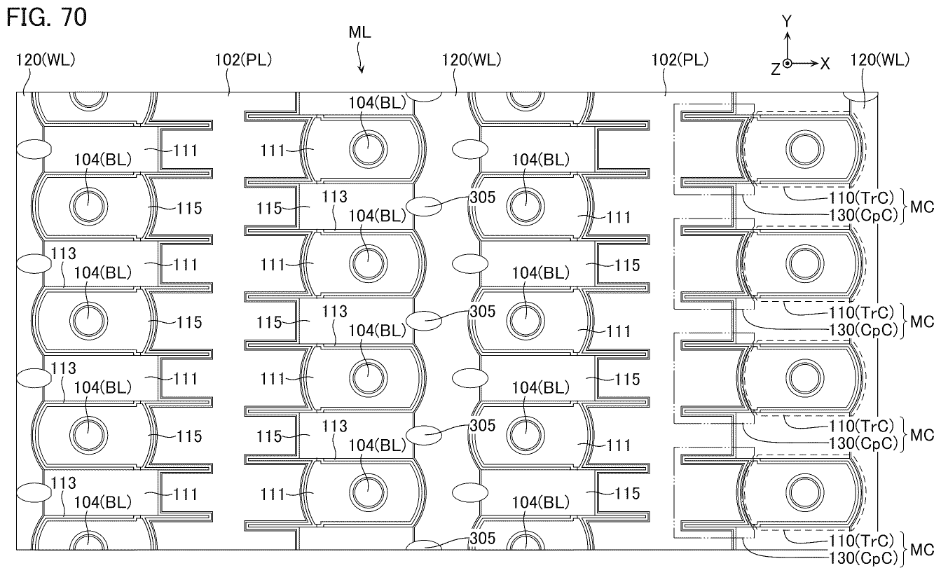

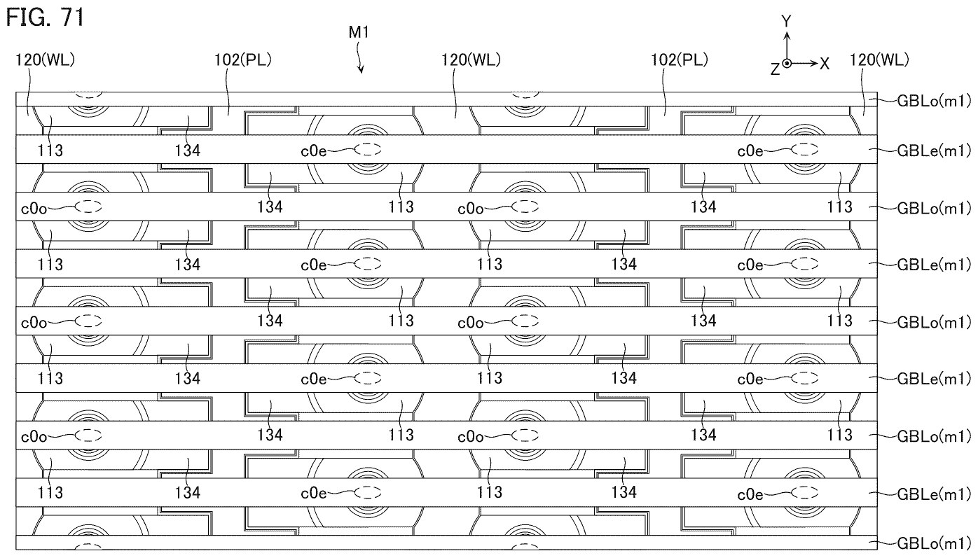

Next, a semiconductor memory device according to the tenth embodiment is described with reference to FIG. 70 and FIG. 71. FIG. 70 is a schematic X-Y cross-sectional view illustrating a configuration of a part of the semiconductor memory device. FIG. 71 is a schematic plan view illustrating a configuration of a part of the semiconductor memory device. In the following description, configurations similar to those of the sixth embodiment are attached by the same reference numerals and their descriptions are omitted.

The semiconductor memory device according to the tenth embodiment is basically configured similarly to the semiconductor memory device according to the sixth embodiment.

Here, as illustrated in FIG. 64, in the semiconductor memory device according to the sixth embodiment, a plurality of via wirings 104 are disposed so as to form two rows that differ in position in the X-direction between two conductive layers 120 adjacent in the X-direction. In focusing on these plurality of via wirings 104, a position in the Y-direction of one of the plurality of via wirings 104 included in one row approximately coincides with any of the positions in the Y-direction of the plurality of via wirings 104 included in the other row. In focusing on these plurality of via wirings 104, each of the positions in the Y-direction of the plurality of via wirings 104 included in the row disposed on one side in the X-direction with respect to the conductive member 102 approximately coincides with any of the positions in the Y-direction of the plurality of via wirings 104 included in the row disposed on the other side in the X-direction with respect to the conductive member 102.

As illustrated in FIG. 70, in the semiconductor memory device according to the tenth embodiment, a plurality of via wirings 104 are also disposed so as to form two rows that differ in position in the X-direction between two conductive layers 120 adjacent in the X-direction. However, in focusing on these plurality of via wirings 104, a position in the Y-direction of the plurality of via wirings 104 included in one row does not coincide with any of the positions in the Y-direction of the plurality of via wirings 104 included in the other row. In focusing on these plurality of via wirings 104, each of the positions in the Y-direction of the plurality of via wirings 104 included in the row disposed on one side in the X-direction with respect to the conductive member 102 does not coincide with any of the positions in the Y-direction of the plurality of via wirings 104 included in the row disposed on the other side in the X-direction with respect to the conductive member 102.

For example, in the example of FIG. 70, each of the positions in the Y-direction of the plurality of via wirings 104 included in the row disposed on one side in the X-direction with respect to the conductive member 102 approximately coincides with an intermediate position of any two via wirings 104 adjacent in the Y-direction among the plurality of via wirings 104 included in the row disposed on the other side in the X-direction with respect to the conductive member 102. Each of the positions in the Y-direction of the plurality of via wirings 104 included in the row disposed on one side in the X-direction with respect to the conductive member 102 is between the positions in the Y-direction of any two via wirings 104 adjacent in the Y-direction among the plurality of via wirings 104 included in the row disposed on the other side in the X-direction with respect to the conductive member 102.

In addition, the semiconductor memory device according to the tenth embodiment does not include the wiring layer M0.

In the tenth embodiment, as illustrated in FIG. 71, both of the global bit lines GBLo, GBLe in the wiring layer M1 are disposed at positions that overlap with a plurality of corresponding bit lines BL when viewed in the Z-direction. These plurality of global bit lines GBLo, GBLe are in direct contact with the via-contact electrodes c0o, c0e on their lower surfaces.

With such a configuration, the configuration corresponding to the wiring layer M0 and the plurality of via-contact electrodes c1o, c1e can be omitted. Therefore, compared with the first embodiment, a manufacturing cost can be reduced.

### Eleventh Embodiment

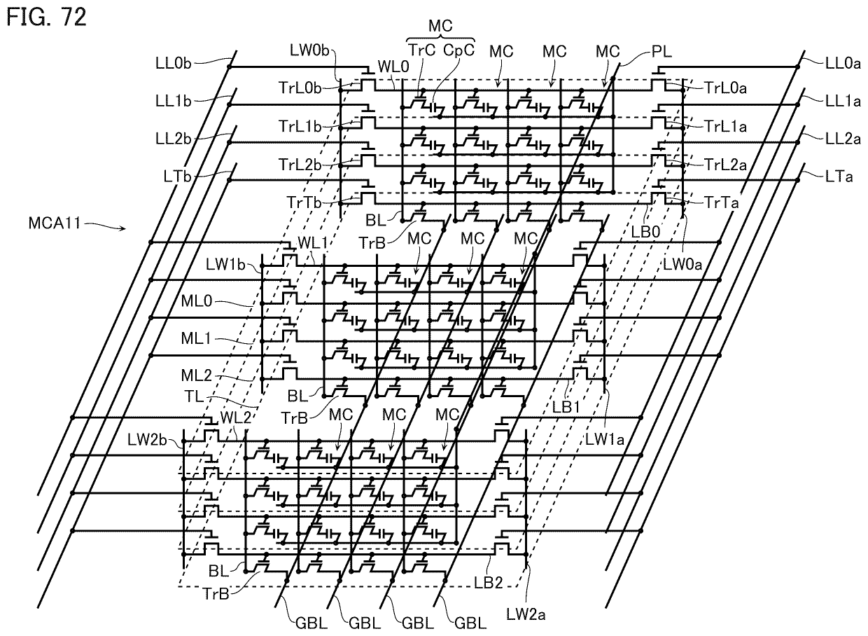

Next, a semiconductor memory device according to the eleventh embodiment is described with reference to FIG. 72 to FIG. 74. In the following description, configurations similar to those of the first embodiment are attached by the same reference numerals and their descriptions are omitted.

### [Circuit Configuration]

FIG. 72 is a schematic circuit diagram illustrating a configuration of a part of the semiconductor memory device.

The semiconductor memory device according to the eleventh embodiment is basically configured similarly to the semiconductor memory device according to the first embodiment.

However, as illustrated in FIG. 72, a memory cell array MCA11 according to the eleventh embodiment includes a transistor layer TL in addition to the configurations included in the memory cell array MCA according to the first embodiment.

The transistor layer TL includes a plurality of bit line select lines LB0 to LB2 and a plurality of transistors TrB connected to the plurality of bit line select lines LB0 to LB2. Source electrodes of the transistors TrB are connected to the global bit lines GBL. Drain electrodes of the transistors TrB are connected to the bit lines BL. That is, in the embodiment, the plurality of bit lines BL are electrically connected to the respective global bit line GBL via the transistors TrB. Gate electrodes of the transistors TrB are connected to any of the bit line select lines LB0 to LB2.

In addition, the transistor layer TL includes a plurality of transistors TrTa, TrTb (hereinafter referred to as “transistors TrT” in some cases), each of which is disposed corresponding to the plurality of bit line select lines LB0 to LB2. Drain electrodes of the transistors TrT are connected to any of the bit line select lines LB0 to LB2. Source electrodes of the transistors TrT are connected to the respective word line select lines LW. Gate electrodes of the transistors TrT are connected to respective wirings LTa, LTb (hereinafter referred to as “wirings LT” in some cases).

Note that the wiring LTa is connected in common to all the transistors TrTa. Similarly, the wiring LTb is connected in common to all the transistors TrTb.

### [Structure]

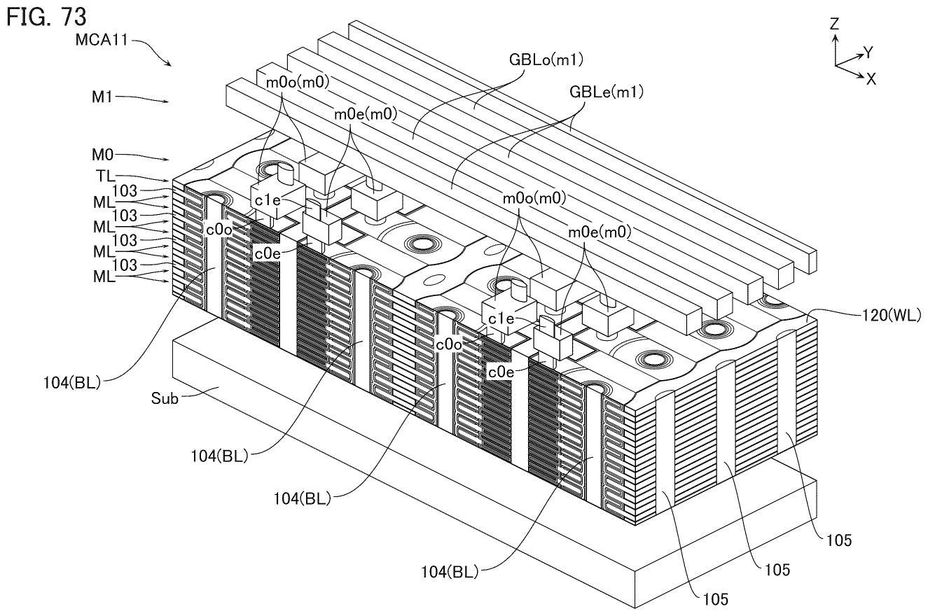

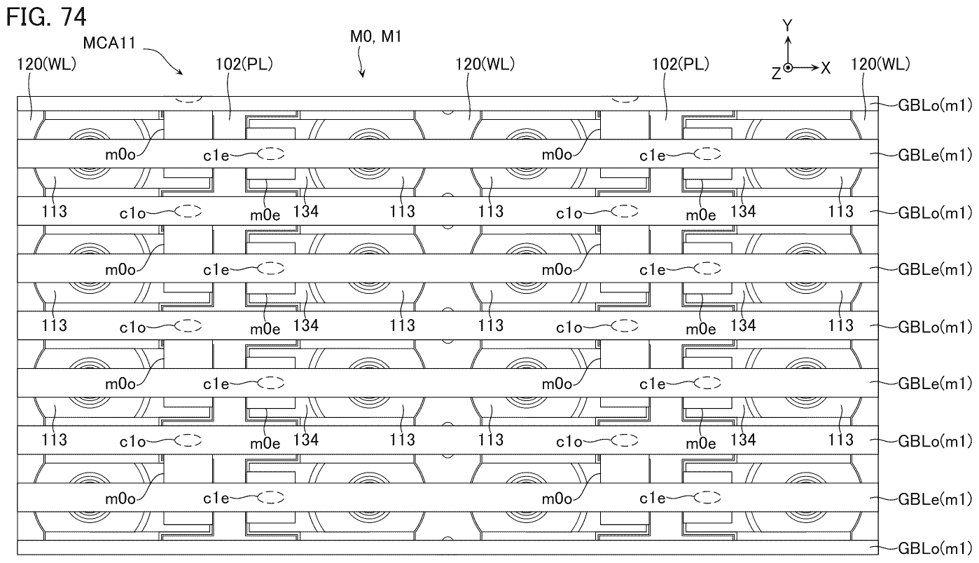

FIG. 73 is a schematic perspective view illustrating a configuration of a part of the semiconductor memory device. FIG. 74 is a schematic plan view illustrating a configuration of a part of the semiconductor memory device.

As illustrated in FIG. 73, the memory cell array MCA11 includes the transistor layer TL disposed between the plurality of memory layers ML and the wiring layer M0.

The transistor layer TL is basically configured similarly to the memory layers ML.

However, the semiconductor layers 111, the insulating layers 112, and the conductive layers 113 in the transistor layer TL function as channel regions, gate insulating films, and gate electrodes of the transistors TrB, respectively. The conductive layers 120 in the transistor layer TL function as the bit line select lines LB0 to LB2. The conductive layers 134 in the transistor layer TL function as source electrodes of the transistors TrB.

In the eleventh embodiment, the via-contact electrodes c0o, c0e are connected to the conductive layers 134 in the transistor layer TL.

The semiconductor memory device according to the eleventh embodiment may include the plurality of insulating members 205 (FIG. 60), the plurality of insulating members 305 (FIG. 61), or the plurality of insulating members 405 (FIG. 62) instead of the plurality of insulating members 105. When the semiconductor memory device according to the eleventh embodiment includes the plurality of insulating members 405, the semiconductor memory device according to the eleventh embodiment may include the conductive layers 420 (FIG. 62) instead of the conductive layers 120.

### Twelfth Embodiment

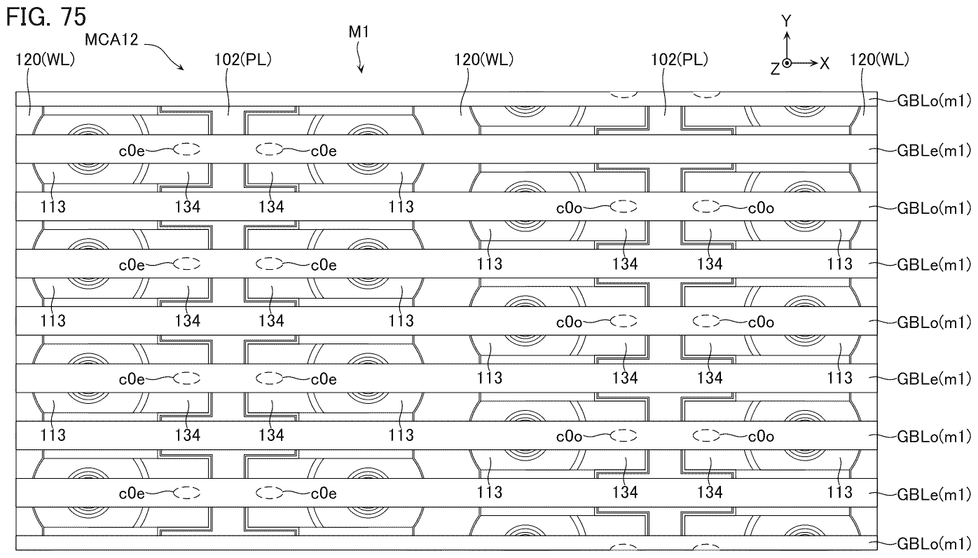

Next, a semiconductor memory device according to the twelfth embodiment is described with reference to FIG. 75. FIG. 75 is a schematic plan view illustrating a configuration of a part of the semiconductor memory device. In the following description, configurations similar to those of the sixth embodiment are attached by the same reference numerals and their descriptions are omitted.

The semiconductor memory device according to the twelfth embodiment is basically configured similarly to the semiconductor memory device according to the sixth embodiment.

However, a memory cell array MCA12 according to the twelfth embodiment includes the transistor layer TL in addition to the configurations included in the memory cell array MCA according to the sixth embodiment.

In the twelfth embodiment, similarly to the eleventh embodiment, the via-contact electrodes c0o, c0e are connected to the conductive layers 134 in the transistor layer TL.

### Thirteenth Embodiment

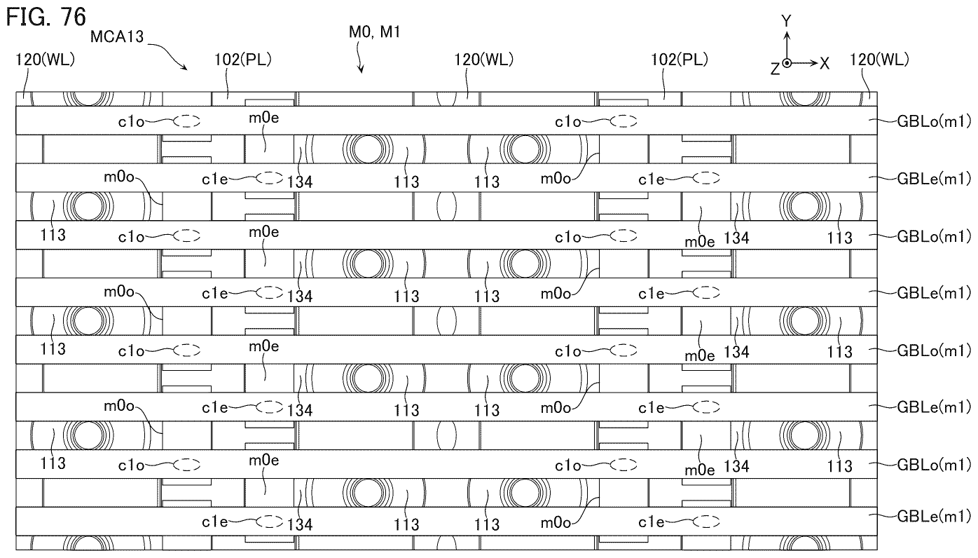

Next, a semiconductor memory device according to the thirteenth embodiment is described with reference to FIG. 76. FIG. 76 is a schematic plan view illustrating a configuration of a part of the semiconductor memory device. In the following description, configurations similar to those of the eighth embodiment are attached by the same reference numerals and their descriptions are omitted.

The semiconductor memory device according to the thirteenth embodiment is basically configured similarly to the semiconductor memory device according to the eighth embodiment.

However, a memory cell array MCA13 according to the thirteenth embodiment includes the transistor layer TL in addition to the configurations included in the memory cell array MCA according to the eighth embodiment.

In the thirteenth embodiment, similarly to the eleventh embodiment, the via-contact electrodes c0o, c0e are connected to the conductive layers 134 in the transistor layer TL.

The semiconductor memory device according to the thirteenth embodiment may include the plurality of insulating members 205 (FIG. 60), the plurality of insulating members 305 (FIG. 61), or the plurality of insulating members 405 (FIG. 62) instead of the plurality of insulating members 105. When the semiconductor memory device according to the thirteenth embodiment includes the plurality of insulating members 405, the semiconductor memory device according to the thirteenth embodiment may include the conductive layers 420 (FIG. 62) instead of the conductive layers 120.

### Fourteenth Embodiment

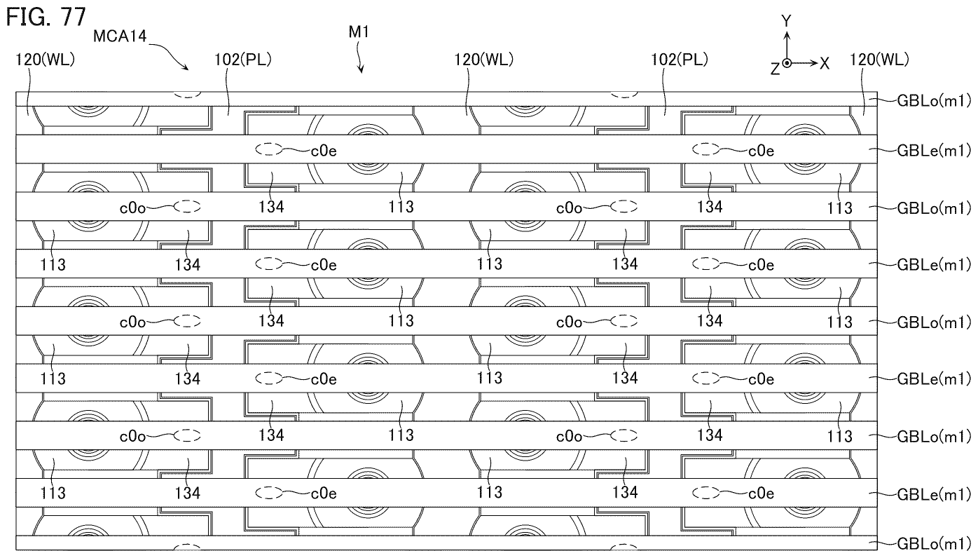

Next, a semiconductor memory device according to the fourteenth embodiment is described with reference to FIG. 77. FIG. 77 is a schematic plan view illustrating a configuration of a part of the semiconductor memory device. In the following description, configurations similar to those of the tenth embodiment are attached by the same reference numerals and their descriptions are omitted.

The semiconductor memory device according to the fourteenth embodiment is basically configured similarly to the semiconductor memory device according to the tenth embodiment.

However, a memory cell array MCA14 according to the fourteenth embodiment includes the transistor layer TL in addition to the configurations included in the memory cell array MCA according to the tenth embodiment.

In the fourteenth embodiment, similarly to the eleventh embodiment, the via-contact electrodes c0o, c0e are connected to the conductive layers 134 in the transistor layer TL.

### Fifteenth Embodiment

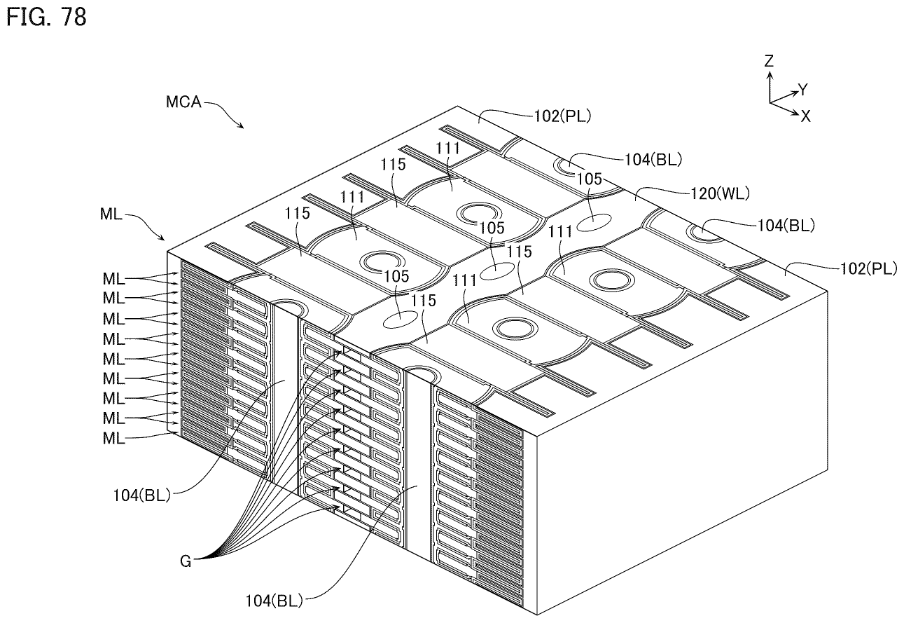

Next, a semiconductor memory device according to the fifteenth embodiment is described with reference to FIG. 78. FIG. 78 is a schematic plan view illustrating a configuration of a part of the semiconductor memory device. In the following description, configurations similar to those of the first embodiment are attached by the same reference numerals and their descriptions are omitted.

The semiconductor memory device according to the fifteenth embodiment is basically configured similarly to the semiconductor memory device according to the first embodiment.

However, as illustrated in FIG. 78, in the fifteenth embodiment, a cavity G is provided between two conductive layers 120 adjacent in the Z-direction.

For example, the cavity G can be formed by a method, such as wet etching, after a process of forming the conductive layers 120 is performed and before a process of forming the insulating members 105 is performed.

Such a configuration allows decreasing an electrostatic capacitance between two conductive layers 120 adjacent in the Z-direction and achieving the speed-up of the operation.

Note that in the semiconductor memory devices according to the second embodiment to the fourteenth embodiment, similarly to the semiconductor memory device according to the fifteenth embodiment, the cavity G may be provided between two conductive layers 120 adjacent in the Z-direction.

### Other Embodiments

The semiconductor memory devices according to the first embodiment to the fifteenth embodiment have been described above. However, the semiconductor memory devices according to these embodiments are only examples and specific configurations and the like are adjustable as appropriate.

For example, in the first embodiment to the fifteenth embodiment, the wiring layers M0, M1 are disposed above the memory cell arrays MCA, MCA11, MCA12, MCA13, MCA14 (hereinafter referred to as “memory cell array MCA and the like”) (a side opposite to the semiconductor substrate Sub with respect to the memory cell array MCA and the like). However, the wiring layers M0, M1 may be disposed below the memory cell array MCA and the like (a semiconductor substrate Sub side with respect to the memory cell array MCA and the like).

In the eleventh embodiment to the fourteenth embodiment, when the wiring layers M0, M1 are disposed below the memory cell array MCA and the like, the transistor layer TL may be disposed below the plurality of memory layers ML (between the plurality of memory layers ML and the wiring layer M0).

In addition, in the semiconductor memory devices according to the first embodiment to the fifteenth embodiment, the via wirings 104 that function as bit lines contain a conductive oxide, such as indium tin oxide (ITO). However, such a conductive oxide may be contained in the transistor structures 110 rather than in the via wirings 104 extending in the Z-direction. The via wirings 104 and the transistor structures 110 may contain other materials and the like.

Moreover, in the semiconductor memory devices according to the first embodiment to the fifteenth embodiment, the conductive layer 113 that functions as the gate electrode of the transistor TrC may be opposed to only one of the upper surface and the lower surface of the semiconductor layer 111 that functions as the channel region of the transistor TrC.

Furthermore, in the semiconductor memory devices according to the first embodiment to the fifteenth embodiment, a semiconductor layer that functions as the channel region of the transistor TrC may be opposed to the upper surface and the lower surface of a conductive layer that functions as the gate electrode of the transistor TrC.

In the above description, examples in which the capacitor CpC is employed as a memory portion connected to the transistor structure 110 have been described. However, the memory portion need not be the capacitor CpC. For example, the memory portion may be one that contains ferroelectric material, ferromagnet material, chalcogen material such as GeSbTe or another material, and stores data using the characteristics of these materials. For example, in any of the structures described above, any of these materials may be included in the insulating layer between the electrodes forming the capacitor CpC.

In addition, the manufacturing methods of the semiconductor memory devices according to the first embodiment to the fifteenth embodiment are also adjustable as appropriate. For example, the order of any two of the processes described above may be changed, or any two of the processes described above may be simultaneously performed.

### [Others]

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate;
a plurality of memory layers arranged in a first direction intersecting with a surface of the substrate;
a first via-wiring extending in the first direction; and
a second via-wiring in a position different from a position of the first via-wiring in a second direction intersecting with the first direction and extending in the first direction, wherein
one of the plurality of memory layers includes:
a first wiring disposed between the first via-wiring and the second via-wiring and extending in a third direction intersecting with the first direction and the second direction;
a first semiconductor layer electrically connected to the first via-wiring;
a first gate electrode opposed to the first semiconductor layer and electrically connected to the first wiring;
a first memory portion electrically connected to the first semiconductor layer and disposed on an opposite side of the first wiring with respect to the first semiconductor layer in the second direction;
a second semiconductor layer electrically connected to the second via-wiring;
a second gate electrode opposed to the second semiconductor layer and electrically connected to the first wiring; and
a second memory portion electrically connected to the second semiconductor layer and disposed on an opposite side of the first wiring with respect to the second semiconductor layer in the second direction.

2. The semiconductor memory device according to claim 1, wherein
the first gate electrode is opposed to a surface on one side and a surface on the other side in the first direction and a surface on one side and a surface on the other side in the third direction of the first semiconductor layer.

3. The semiconductor memory device according to claim 1, wherein
a plurality of cavities are provided between a plurality of the first wirings arranged in the first direction corresponding to the plurality of memory layers.

4. The semiconductor memory device according to claim 1, wherein
the first memory portion includes:
a first electrode electrically connected to the first semiconductor layer;
a second electrode opposed to the first electrode; and
an insulating layer disposed between the first electrode and the second electrode.

5. The semiconductor memory device according to claim 1, wherein
the first semiconductor layer contains at least one element of Gallium (Ga) and Aluminum (Al) and contains Indium (In), zinc (Zn), and oxygen (O).

6. A semiconductor device comprising:
a substrate;
a plurality of memory layers arranged in a first direction intersecting with a surface of the substrate; and
a plurality of via-wirings arranged to form a first row and a second row, the first row and the second row being disposed in different positions in a second direction intersecting with the first direction, wherein
the first row includes a plurality of first via-wirings extending in the first direction and arranged in a third direction intersecting with the first direction and the second direction, and
the second row includes a plurality of second via-wirings extending in the first direction and arranged in the third direction, and
one of the plurality of memory layers includes:
a first wiring disposed between the plurality of first via-wirings and the plurality of second via-wirings and extending in the third direction;
a plurality of first semiconductor layers electrically connected to the plurality of first via-wirings;
a plurality of first gate electrodes opposed to the plurality of first semiconductor layers and electrically connected to the first wiring;
a plurality of first memory portions electrically connected to the plurality of first semiconductor layers and disposed on an opposite side of the first wiring with respect to the plurality of first semiconductor layers in the second direction;
a plurality of second semiconductor layers electrically connected to the plurality of second via-wirings;
a plurality of second gate electrodes opposed to the plurality of second semiconductor layers and electrically connected to the first wiring; and
a plurality of second memory portions electrically connected to the plurality of second semiconductor layers and disposed on an opposite side of the first wiring with respect to the plurality of second semiconductor layers in the second direction.

7. The semiconductor memory device according to claim 6, further comprising
a plurality of first insulating members arranged in the third direction along the first wiring in a first cross sectional surface extending in the second direction and the third direction and including the first wiring.

8. The semiconductor memory device according to claim 7, further comprising
a plurality of second insulating members arranged alternately with the plurality of first semiconductor layers in the third direction, wherein
a position in the third direction of one of the plurality of first insulating members corresponds to a position in the third direction of any of the plurality of second insulating members.

9. The semiconductor memory device according to claim 7, wherein
a position in the second direction of one of the plurality of first insulating members coincides with a middle position in the second direction of the first wiring.

10. The semiconductor memory device according to claim 7, wherein
one of the plurality of first insulating members is disposed on one side in the second direction with respect to a middle position in the second direction of the first wiring.

11. The semiconductor memory device according to claim 7, wherein
a part of the plurality of first insulating members is disposed on one side in the second direction with respect to a middle position in the second direction of the first wiring, and
the other part of the plurality of first insulating members is disposed on the other side in the second direction with respect to the middle position in the second direction of the first wiring.

12. The semiconductor memory device according to claim 7, further comprising
a plurality of second insulating members arranged alternately with the plurality of first semiconductor layers in the third direction, wherein
a number of the plurality of first insulating members arranged in the third direction is smaller than a number of the plurality of second insulating members arranged in the third direction.

13. The semiconductor memory device according to claim 6, further comprising:
a first wiring layer disposed on one side in the first direction with respect to the plurality of memory layers; and
a second wiring layer disposed between the plurality of memory layers and the first wiring layer, wherein
the first wiring layer includes a plurality of second wirings arranged in the third direction and extending in the second direction, and
the second wiring layer includes a plurality of third wirings extending in the third direction in a position where any of the plurality of first via-wirings or any of the plurality of second via-wirings overlaps with any of the plurality of second wirings when viewed in the first direction.

14. The semiconductor memory device according to claim 6, further comprising
a first wiring layer disposed on one side in the first direction with respect to the plurality of memory layers, wherein
the first wiring layer includes a plurality of second wirings,
each of a part of the plurality of second wirings is disposed in a position overlapping with any of the plurality of first via-wirings when viewed in the first direction, and
each of the others of the plurality of second wirings is disposed in a position overlapping with any of the plurality of second via-wirings when viewed in the first direction.

15. The semiconductor memory device according to claim 14, wherein
the plurality of second wirings are arranged in the third direction and extending in the second direction.

16. The semiconductor memory device according to claim 14, wherein
the plurality of second wirings extend in a direction intersecting with the second direction and the third direction in a second cross sectional surface, the second cross sectional surface extending in the second direction and the third direction and including the plurality of second wirings.

17. The semiconductor memory device according to claim 6, wherein
a position in the third direction of one of the plurality of first via-wirings approximately coincides with any of positions in the third direction of the plurality of second via-wirings.

18. The semiconductor memory device according to claim 6, wherein
a position in the third direction of one of the plurality of first via-wirings does not coincide with any of positions in the third direction of the plurality of second via-wirings.

19. The semiconductor memory device according to claim 6, further comprising:
a fourth wiring extending in the first direction and the third direction and connected to the plurality of first memory portions; and
a plurality of third via-wirings disposed on an opposite side of the plurality of first via-wirings with respect to the fourth wiring in the second direction, arranged in the third direction, and extending in the first direction, wherein
one of the plurality of memory layers further includes:
a fifth wiring disposed on an opposite side of the first wiring with respect to the plurality of third via-wirings in the second direction and extending in the third direction;
a plurality of third semiconductor layers electrically connected to the plurality of third via-wirings;
a plurality of third gate electrodes opposed to the plurality of third semiconductor layers and electrically connected to the fifth wiring; and
a plurality of third memory portions disposed between the plurality of third semiconductor layers and the fourth wiring and electrically connected to the plurality of third semiconductor layers and the fourth wiring.

20. The semiconductor memory device according to claim 19, wherein
a position in the third direction of one of the plurality of first via-wirings approximately coincides with any of positions in the third direction of the plurality of third via-wirings.

21. The semiconductor memory device according to claim 19, wherein
a position in the third direction of one of the plurality of first via-wirings does not coincide with any of positions in the third direction of the plurality of third via-wirings.
